(19) United States
(12) Patent Application Publication
(10) Pub. No.: US 2025/0314703 A1
(43) Pub. Date: Oct. 9, 2025

(54) METHOD FOR DETERMINING BATTERY FIRE RISK BASED ON VOLTAGE MEASUREMENTS

(71) Applicant: LG Energy Solution, Ltd., Seoul (KR)

(72) Inventors: Ha Eun Byun, Daejeon (KR); Cheol Taek Kim, Daejeon (KR); Jung Uk Park, Daejeon (KR); Jung Hwan Choi, Daejeon (KR); Young Min Kim, Daejeon (KR)

(21) Appl. No.: 19/169,957

(22) Filed: Apr. 3, 2025

(30) Foreign Application Priority Data
Apr. 3, 2024 (KR) 10-2024-0045175
May 7, 2024 (KR) 10-2024-0059709
Apr. 2, 2025 (KR) 10-2025-0042886

(51) Int. Cl. G01R 31/3835; G01R 31/367; G01R 31/392; G01R 31/396

(52) U.S. Cl. CPC G01R 31/3835; G01R 31/367; G01R 31/392; G01R 31/396

(57) ABSTRACT

A method concerning on a battery's health includes: providing a battery apparatus comprising a plurality of battery cells; measuring a voltage for each of the plurality of battery cells; processing the plurality of voltages to provide a composite voltage; first determining if any of the plurality of battery cells has a rate of its voltage decrease that is greater than a rate of decrease of the composite voltage over the first predetermined length of time; second determining if any of the plurality of battery cells has a rate of voltage decrease that is greater than a rate of decrease of the composite voltage over the second predetermined length of time; and generating an alert if any battery cell is identified with any of the first determining step and the second determining step.

### INCORPORATION BY REFERENCE

Any and all applications for which a foreign or domestic priority claim is identified in the Application Data Sheet as filed with the present application are hereby incorporated by reference under 37 CFR 1.57.

### TECHNICAL FIELD

The present disclosure relates to technology for abnormal voltage diagnosis of a battery.

### BACKGROUND

Battery systems, for example, those used in electric devices, face significant safety challenges, one of which is the risk of fire. The potential for thermal runaway and fire hazards poses a serious concern. To mitigate these risks, early detection of abnormal conditions leading to fire is essential.

### SUMMARY

The present disclosure provides a method for detecting fire risks in battery cells by measuring their OCV over time, comparing those measurements against an average OCV, and analyzing the rate of change of the OCV differences. The method includes calculating the rate of change for the OCV difference over two different time periods and comparing these rates of change against two separate threshold values. The present disclosure also incorporates a counting mechanism, where the number of instances the rate of change exceeds these thresholds can be used to assess fire risk. A higher count of occurrences where the rate of change exceeds the threshold indicates a higher likelihood of fire risk.

### Method of Concerning on Battery's Health

One aspect of the present disclosure provides a method concerning on a battery's health. A battery apparatus comprising a plurality of battery cells is provided. A voltage for each of the plurality of battery cells is measured at a single measurement timeframe, which provides a plurality of voltages of the plurality of battery cells measured at the single measurement timeframe. The plurality of voltages for the plurality of battery cells measured at the single measurement timeframe are processed to provide a composite voltage for the plurality of battery cells for the single measurement timeframe. The step of measuring a voltage multiple times is repeated to provide multiple voltages for each battery cell measured at multiple measurement timeframes, which provides multiple sets of voltages for the plurality of battery cells such that each set of voltages represents voltages for the plurality of battery cells measured at one of the multiple measurement timeframes. The step of processing each set of voltages is repeated to provide multiple composite voltages for the plurality of battery cells such that each of the multiple composite voltages represents a composite voltage for the plurality of battery cells at one of the multiple measurement timeframes. There is a first determining step to determine if any of the plurality of battery cells has a rate of its voltage decrease that is greater, by at least a first predetermined threshold over a first predetermined length of time, than a rate of decrease of the composite voltage for the plurality of battery cells over the first predetermined length of time. There is a second determining step to determine if any of the plurality of battery cells has a rate of voltage decrease that is greater, by at least a second predetermined threshold over a second predetermined length of time, than a rate of decrease of the composite voltage for the plurality of battery cells over the second predetermined length of time. An alert is generated if any battery cell is identified with any of the first determining step and the second determining step. The first predetermined threshold is substantially smaller than the second predetermined threshold while the first predetermined length of time is longer than the second predetermined length of time such that the first determining step is to identify any battery cell that has its voltage decreasing substantially slower than any battery cell that would be identified with the second determining step and therefore would not be identified with the second determining step.

### Voltages

In some embodiments, the voltage measured is an open circuit voltage (OCV), and the composite voltage is an average voltage.

No Alert over Third Predetermined Length of Time

In some embodiments, no alert is generated even if any of the plurality of battery cells has a rate of voltage decrease being greater than the first predetermined threshold over a third predetermined length of time, when the third predetermined length of time is shorter than the second predetermined length of time and further when the rate of voltage decrease for any of the plurality of battery cells is within an acceptable range of fluctuation of the rate of voltage decrease for individual cells over the third predetermined length of time. In some embodiments, the third predetermined length of time is within a range formed with two selected from the group consisting of 1 hour, 2 hours, 3 hours, 4 hours, 5 hours, 6 hours, 7 hours, 8 hours, 10 hours, 11 hours, 12 hours, 13 hours, 14 hours, 15 hours, 16 hours, 17 hours, 18 hours, 19 hours, 20 hours, 21 hours, 22 hours, 23 hours, 1 day, 2 days, 3 days, 4 days, 5 days, 6 days, 7 days, 8 days, 9 days, and 10 days. In some embodiments, the acceptable range of fluctuation is within a range formed with two selected from the group consisting of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 mV/t. In some embodiments, no alert is generated even if any of the plurality of battery cells has a rate of voltage decrease being greater than the first predetermined threshold over the third predetermined length of time when the rate of voltage decrease for any of the plurality of battery cells is within an acceptable range of fluctuation of the rate of voltage decrease for individual cells over the third predetermined length of time.

### Alert

In some embodiments, the alert comprises information suggesting a consultation about the battery's health, suggesting a service with regard to the battery apparatus, and/or replacing at least part of the battery apparatus.

### Third Determining Step

In some embodiments, there is a third determining step to determine if any of the plurality of battery cells has a rate of its voltage decrease that is greater than a third predetermined threshold over a third predetermined length of time. An alert is generated if any battery cell is identified with any of the first determining step, the second determining step, and the third determining step, wherein the second predetermined threshold is substantially smaller than the third predetermined threshold while the third predetermined length of time is shorter than the second predetermined length of time.

### Voltage Measurement

In some embodiments, measuring the voltage for each of the plurality of battery cells at the single measurement timeframe occurs simultaneously or consecutively such that measurements for the plurality of battery cells are completed within a generally same timeframe.

### First Determining Step

In some embodiments, in the first determining step, for each of the plurality of battery cells, a difference between the voltage of the battery cell and the composite voltage for the plurality of battery cells is computed for a first measurement timeframe of the multiple measurement timeframes, which provides a first set of values for the difference for the plurality of battery cells for the first measurement timeframe such that the first set of values comprises a value for the difference for each of the plurality of cells for the first measurement timeframe. The computing step is repeated to compute a difference for additional measurement timeframes of the multiple timeframes, which provides additional sets of values for the difference for the plurality of battery cells for the additional measurement timeframes such that each set of values comprises a value for the difference for each of the plurality of cells for one measurement timeframe of the additional measurement timeframes. For each of the plurality of battery cells, a rate of change in the difference over the first predetermined length of time is computed using at least part of the first set of values and the additional sets of values; and it is determined if there is any battery cell having a rate of voltage decrease over the first predetermined length of time greater than the first predetermined threshold using the computed rate of change for each of the plurality of battery cells. In some embodiments, the step of computing a rate of change in the difference over the first predetermined length of time computes the rate of change in the difference for the first predetermined length of time beginning at the first measurement timeframe. For each of the plurality of battery cells, the step of computing a rate of change in the difference is repeated over the first predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes. At least part of the rates of change in the difference as computed for each of the plurality of battery cells are used to determine if there is any battery cell having a rate of voltage decrease over the first predetermined length of time greater than the first predetermined threshold for the first predetermined length of time beginning at one or more of the additional measurement timeframes. In some embodiments, when at least one of the plurality of battery cell is determined to have its rate of voltage decrease greater than the first predetermined threshold over the first predetermined length of time beginning any of the measurement timeframes, the battery cell is identified, which causes generating the alert. In some embodiments, the step of first determining further comprises: counting, for each of the plurality of battery cells, each time when the battery cell is determined to have its rate of voltage decrease over the first predetermined length of time to be greater than the first predetermined threshold; and determining, for each of the plurality of battery cells, if counting reaches a predetermined counting threshold. In some embodiments, when counting for one of the plurality of battery cell reaches the predetermined counting threshold, the battery cell is identified, which causes generating the alert.

### Second Determining Step

In some embodiments, the second determining step comprises: for each of the plurality of battery cells, computing a rate of change in the difference over the second predetermined length of time using at least part of the first set of values and the additional sets of values; and determining if there is any battery cell having a rate of voltage decrease over the second predetermined length of time greater than the second predetermined threshold using the computed rate of change for each of the plurality of battery cells. In some embodiments, the step of computing a rate of change in the difference over the second predetermined length of time computes the rate of change in the difference for the second predetermined length of time beginning at the first measurement timeframe or another measurement timeframe. For each of the plurality of battery cells, the step of computing a rate of change in the difference is repeated over the second predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes. At least part of the rates of change in the difference as computed for each of the plurality of battery cells are used to determine if there is any battery cell having a rate of voltage decrease over the second predetermined length of time greater than the second predetermined threshold for the second predetermined length of time beginning at one or more of the additional measurement timeframes. In some embodiments, when at least one of the plurality of battery cell is determined to have its rate of voltage decrease greater than the second predetermined threshold over the second predetermined length of time beginning any of the measurement timeframes, the battery cell is identified, which causes generating the alert. In some embodiments, the second determining step further comprises: counting, for each of the plurality of battery cells, each time when the battery cell is determined to have its rate of voltage decrease over the second predetermined length of time to be greater than the second predetermined threshold; and determining, for each of the plurality of battery cells, if counting reaches a predetermined counting threshold. In some embodiments, when counting for one of the plurality of battery cell reaches the predetermined counting threshold, the battery cell is identified, which causes generating the alert.

### Second Determining Step—Continued

In some embodiments, in the second determining step, for each of the plurality of battery cells, a difference between the voltage of the battery cell and the composite voltage for the plurality of battery cells is computed for a first measurement timeframe of the multiple measurement timeframes, which provides a first set of values for the difference for the plurality of battery cells for the first measurement timeframe such that the first set of values comprises a value for the difference for each of the plurality of cells for the first measurement timeframe. The step of computing a difference is repeated for additional measurement timeframes of the multiple timeframes, which provides additional sets of values for the difference for the plurality of battery cells for the additional measurement timeframes such that each set of values comprises a value for the difference for each of the plurality of cells for one measurement timeframe of the additional measurement timeframes. For each of the plurality of battery cells, a rate of change in the difference over the second predetermined length of time is computed using at least part of the first set of values and the additional sets of values, and it is determined if there is any battery cell having a rate of voltage decrease over the second predetermined length of time greater than the second predetermined threshold using the computed rate of change for each of the plurality of battery cells. In some embodiments, the step of computing a rate of change in the difference over the second predetermined length of time computes the rate of change in the difference for the second predetermined length of time beginning at the first measurement timeframe or another measurement timeframe. For each of the plurality of battery cells, the step of computing a rate of change in the difference is repeated over the second predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes. At least part of the rates of change in the difference as computed for each of the plurality of battery cells are used to determine if there is any battery cell having a rate of voltage decrease over the second predetermined length of time greater than the second predetermined threshold for the second predetermined length of time beginning at one or more of the additional measurement timeframes. In some embodiments, when at least one of the plurality of battery cell is determined to have its rate of voltage decrease greater than the second predetermined threshold over the second predetermined length of time beginning any of the measurement timeframes, the battery cell is identified, which causes generating the alert. In some embodiments, the second determining step further comprises: counting, for each of the plurality of battery cells, each time when the battery cell is determined to have its rate of voltage decrease over the second predetermined length of time to be greater than the second predetermined threshold; and determining, for each of the plurality of battery cells, if counting reaches a predetermined counting threshold. In some embodiments, when counting for one of the plurality of battery cell reaches the predetermined counting threshold, the battery cell is identified, which causes generating the alert.

### Non-Transitory Computer Readable Medium

Another aspect of the present disclosure provides a non-transitory computer readable medium storing instructions that, when executed, performs the method provided herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates a block diagram of an electronic device, in accordance with one embodiment.

FIG. 2 illustrates a block diagram of another electronic device, in accordance with one embodiment.

FIG. 3 is a graph illustrating Open Circuit Voltage (OCV) measurement at corresponding timepoints for a certain length of time for each battery cell of a battery module, in accordance with one embodiment.

FIG. 4 is a graph illustrating OCV measurements of multiple battery cells including first, second, third, fourth, and fifth battery cells, at corresponding timepoints and an average OCV thereof for a certain length of time.

FIG. 5A is a graph illustrating the OCV measurement for battery cell 1, along with the average OCV, in accordance with one embodiment.

FIG. 5B is a graph showing the difference between the OCV values of battery cell 1 and the average OCV.

FIG. 5C is a graph depicting the slope of the OCV difference values over a shorter-term (or first)length of time for battery cell 1, compared to a shorter-term threshold.

FIG. 5D is a graph representing the count of occurrences where the slope shown in FIG. 5C falls below the shorter-term threshold level.

FIG. 5E is a graph illustrating a moving average calculated over the shorter-term length of time for the battery cell 1.

FIG. 5F is a graph representing the count of occurrences based on the moving average calculation.

FIG. 5G is a graph illustrating a weighted moving average calculated over the shorter-term length of time for the battery cell 1.

FIG. 5H is a graph illustrating the count of occurrences based on the weighted moving average calculation.

FIG. 5I is a graph illustrating the slope from FIG. 5C alongside the average slope for multiple battery cells.

FIG. 5J is a graph illustrating the slope of the OCV difference values over a longer-term (or second) length of time for battery cell 1, compared to a longer-term threshold.

FIG. 5K is a graph showing the count of occurrences where the slope of FIG. 5F falls below the longer-term threshold.

FIG. 5L is a graph illustrating a moving average calculated over the longer-term length of time for the battery cell 1.

FIG. 5M is a graph representing the count of occurrences based on the moving average calculation.

FIG. 5N is a graph illustrating a weighted moving average calculated over the longer-term length of time for the battery cell 1.

FIG. 5O is a graph illustrating the count of occurrences based on the weighted moving average calculation.

FIG. 5P is a graph depicting the slope from FIG. 5J alongside the average slope for multiple battery cells.

FIG. 5Q is a graph comparing the slopes FIG. 5C and FIG. 5F with their respective short- and long-term thresholds.

FIG. 6A is a graph illustrating the OCV measurement for battery cell 2, along with the average OCV, in accordance with one embodiment.

FIG. 6B is a graph showing the difference between the OCV values of battery cell 2 and the average OCV.

FIG. 6C is a graph depicting the slope of the OCV difference values over a shorter-term length of time for battery cell 2, compared to a shorter-term threshold.

FIG. 6D is a graph representing the count of occurrences where the slope shown in FIG. 6C falls below the shorter-term threshold level.

FIG. 6E is a graph illustrating a moving average calculated over the shorter-term length of time for the battery cell 2.

FIG. 6F is a graph representing the count of occurrences based on the moving average calculation.

FIG. 6G is a graph illustrating a weighted moving average calculated over the shorter-term length of time for the battery cell 2.

FIG. 6H is a graph illustrating the count of occurrences based on the weighted moving average calculation.

FIG. 6I is a graph illustrating the slope from FIG. 6C alongside the average slope for multiple battery cells.

FIG. 6J is a graph illustrating the slope of the OCV difference values over a longer-term length of time for battery cell 2, compared to a longer-term threshold.

FIG. 6K is a graph showing the count of occurrences where the slope of FIG. 6F falls below the longer-term threshold.

FIG. 6L is a graph illustrating a moving average calculated over the longer-term length of time for the battery cell 2.

FIG. 6M is a graph representing the count of occurrences based on the moving average calculation.

FIG. 6N is a graph illustrating a weighted moving average calculated over the longer-term length of time for the battery cell 2.

FIG. 6O is a graph illustrating the count of occurrences based on the weighted moving average calculation.

FIG. 6P is a graph depicting the slope from FIG. 6J alongside the average slope for multiple battery cells.

FIG. 6Q is a graph comparing the slopes FIG. 6C and FIG. 6F with their respective short- and long-term thresholds.

FIG. 7A is a graph illustrating the OCV measurement for battery cell 4, along with the average OCV, in accordance with one embodiment.

FIG. 7B is a graph showing the difference between the OCV values of battery cell 4 and the average OCV.

FIG. 7C is a graph depicting the slope of the OCV difference values over a shorter-term length of time for battery cell 4, compared to a shorter-term threshold.

FIG. 7D is a graph representing the count of occurrences where the slope shown in FIG. 7C falls below the shorter-term threshold level.

FIG. 7E is a graph illustrating a moving average calculated over the shorter-term length of time for the battery cell 4.

FIG. 7F is a graph representing the count of occurrences based on the moving average calculation.

FIG. 7G is a graph illustrating a weighted moving average calculated over the shorter-term length of time for the battery cell 4.

FIG. 7H is a graph illustrating the count of occurrences based on the weighted moving average calculation.

FIG. 7I is a graph illustrating the slope from FIG. 7C alongside the average slope for multiple battery cells.

FIG. 7J is a graph illustrating the slope of the OCV difference values over a longer-term length of time for battery cell 4, compared to a longer-term threshold.

FIG. 7K is a graph showing the count of occurrences where the slope of FIG. 7F falls below the longer-term threshold.

FIG. 7L is a graph illustrating a moving average calculated over the longer-term length of time for the battery cell 4.

FIG. 7M is a graph representing the count of occurrences based on the moving average calculation.

FIG. 7N is a graph illustrating a weighted moving average calculated over the longer-term length of time for the battery cell 4.

FIG. 7O is a graph illustrating the count of occurrences based on the weighted moving average calculation.

FIG. 7P is a graph depicting the slope from FIG. 7J alongside the average slope for multiple battery cells.

FIG. 7Q is a graph comparing the slopes FIG. 7C and FIG. 7F with their respective short- and long-term thresholds.

FIG. 8A is a graph illustrating an expanded view of FIG. 3 over a frequent-term (or third) length of time, for the OCV measurement of the multiple battery cells.

FIG. 8B is a graph illustrating an expanded view of FIG. 4.

FIG. 8C is a graph illustrating an expanded view of FIG. 5A.

FIG. 8D is a graph illustrating an expanded view of FIG. 5B.

FIG. 8E is a graph illustrating an expanded view of FIG. 5C.

FIG. 8F is a graph illustrating an expanded view of FIG. 5E.

FIG. 8G is a graph illustrating an expanded view of FIG. 5G.

FIG. 8H is a graph illustrating an expanded view of FIG. 5J.

FIG. 8I is a graph illustrating an expanded view of FIG. 5L.

FIG. 8J is a graph illustrating an expanded view of FIG. 5N.

FIGS. 9A-12 illustrate flowcharts of a method for detecting battery abnormality, in accordance with one embodiment.

FIG. 13 illustrates one or more computing systems for use with one or more implementations.

### DETAILED DESCRIPTION

Various aspects of the subject matter now will be described and discussed in more detail in terms of some specific embodiments and examples with reference to the accompanying drawings, in which some, but not all embodiments of the disclosure are shown. Like numbers refer to like elements or parts throughout. The presently disclosed subject matter may be embodied in many different forms and should not be construed as limited to the specific embodiments set forth herein. Rather, these embodiments are provided so that this disclosure will satisfy applicable legal requirements. Indeed, many modifications and other embodiments of the presently disclosed subject matter will come to the mind of one skilled in the art to which the presently disclosed subject matter pertains. Therefore, it is to be understood that the presently disclosed subject matter is not to be limited to the specific embodiments disclosed and that modifications and other embodiments are intended to be included within the scope of the appended claims.

### Definitions

### “A,” “An” And “The”

As used herein, the singular form of a word includes the plural, unless the context clearly dictates otherwise. The plural encompasses the singular and vice versa. Thus, the references “a,” “an” and “the” are generally inclusive of the plurals of the respective terms. For example, while the present disclosure has been described in terms of “a” layer, “a” substrate, “a” cell, and the like, more than one of these and other components, including combinations, can be used.

### “About”

The term “about” indicates and encompasses an indicated value and a range above and below that value.

### “Comprise,” “Consisting Essentially Of”, And “Consisting Of”

The words “comprise,” “comprises,” and “comprising” are to be interpreted inclusively rather than exclusively. Likewise, the terms “include,” “including” and “or” should all be construed to be inclusive, unless such a construction is clearly prohibited from the context. A disclosure of an embodiment defined using the term “comprising” is also a disclosure of embodiments “consisting essentially of” and “consisting of” the disclosed components. The phrase “consisting of” excludes any element, step, or ingredient not specified.

### “And/Or”

The term “and/or” used in the context of “X and/or Y” should be interpreted as “X,” “Y,” or “X and Y.”

### Markush Group

As used herein, the term “combination thereof” included in any Markush-type expression means a combination or mixture of one or more elements selected from the group of elements disclosed in the Markush-type expression, and refers to the presence of one or more elements selected from the group. The term “combinations thereof” includes every possible combination of elements to which the term refers.

### “Between”

As used herein, the expression “between” is inclusive of end points.

### Numerical Ranges

Furthermore, all numerical ranges herein should be understood to include all integers, whole or fractions, within the range. Moreover, any numerical range recited herein is intended to include all sub-ranges subsumed therein, and these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth. When ranges are given, any endpoints of those ranges and/or numbers within those ranges can be combined with the scope of the present disclosure.

### “Including,” “Such As” and “For Example”

As used herein, “including,” “such as,” “for example,” and like terms mean “including/such as/for example but not limited to.”

### Combination of Embodiments

As used herein, the term “example,” particularly when followed by a listing of terms, is merely illustrative, and should not be deemed to be exclusive or comprehensive. Any embodiment disclosed herein can be combined with any other embodiment disclosed herein unless explicitly indicated otherwise.

### Overview

### Monitoring Rate of Change in OCV Difference

Detecting potential battery fires is crucial for ensuring the safety and longevity of battery systems. The present disclosure provides a method that involves monitoring the rate of change of the Open Circuit Voltage (OCV) difference between an individual battery cell and the average OCV of a group of cells including the individual cell itself. By analyzing this difference over time, abnormal behaviors that may indicate internal failures, overcharging, or early signs of thermal runaway can be identified before they escalate into hazardous conditions.

### Calculations Involved

The detection method begins by calculating the OCV difference for each cell. This difference, denoted as ΔVᵢ, is obtained by subtracting the average OCV of a set of battery cells (V_{avg}) from the OCV of an individual cell (Vᵢ). Tracking how ΔVᵢ changes over time provides insights into the relative performance and stability of each cell within the system. A significant deviation from the expected range could signal potential issues such as imbalance, degradation, or an emerging failure. To enhance detection accuracy, the rate of change of the OCV difference, represented as d(ΔVᵢ)/dt, is monitored. A rapidly increasing or irregular trend in this rate suggests that a cell is behaving abnormally compared to its peers. Such deviations can indicate internal shorts, excessive self-discharge, or other fault conditions that may lead to overheating and, in extreme cases, a battery fire.

### Long-Term and Short-Term

For robust fault detection, the analysis may be conducted over at least two different time durations: a long-term and a short-term period. The long-term trend, which may span months, helps identify gradual degradation effects such as capacity loss, lithium plating, or persistent imbalances between cells due to aging. On the other hand, the short-term trend, which may be measured over days or weeks, detects more immediate and unexpected changes, which may be indicative of safety risks such as internal shorts, abnormal self-discharge, or localized thermal issues. By combining at least two different timescales, the system can distinguish between normal wear-and-tear and sudden, potentially dangerous failures.

### Threshold-Based Approach

A threshold-based approach is employed to trigger warnings or protective actions. If the rate of change of the OCV difference exceeds a predetermined threshold within either the short-term or long-term monitoring window, an alert may be raised, prompting further investigation or preventive measures such as cell isolation or system shutdown. This method improves early fault detection, reducing the likelihood of catastrophic failures while maintaining the overall health and reliability of the battery system.

### Battery Fire Risk Detection

Battery Monitoring and/or Diagnosis

Batteries are a crucial component in electronic devices, providing the power necessary for the electronic devices to operate and perform their functions. While batteries offer several benefits, they also present challenges. One of the main risks associated with them is the potential for fire, which can result from the chemical and electrical processes occurring within the battery cells. Various factors, such as thermal runaway, overcharging, short circuits, overheating, and battery aging, can trigger these hazardous conditions. In the event of a fire, the safety of the device and its systems may be severely compromised. Given the crucial role of the batteries in electronic devices, ensuring its safety is paramount. As such, the electronic devices may be equipped with some kind of battery monitoring and/or diagnostic devices designed to detect potential fire risks within the battery packs.

### Example Electronic Device

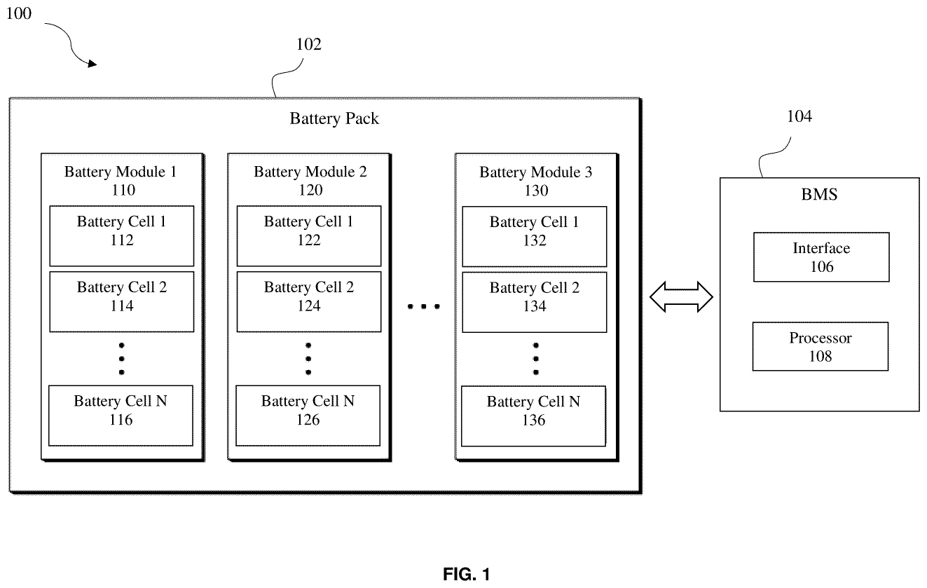

As shown in the non-limiting example illustrated in FIG. 1, the electronic device 100 includes a battery apparatus 102 and a Battery Management System (BMS) 104 that communicates with the battery pack 102 to ensure the battery pack is functioning safely.

### Battery Apparatus

The battery apparatus 102 may include several battery modules 110, 120, 130, and others and may be in constant communication with the BMS 104. The “battery apparatus” may be any device or equipment that involves batteries or parts of batteries. For example, the battery apparatus may be a battery pack, battery unit, battery cell, battery system, battery assembly, battery module, power pack, energy pack, or energy storage unit, etc. In the example illustrated in FIG. 1, the battery apparatus 102 is a battery pack including several battery modules, and each battery module includes one or more battery cells that are connected together to meet certain power needs. It is understood that each battery module can also be referred to as a battery apparatus. In some instances, each battery cell may also be referred to as a battery apparatus. As shown in FIG. 1, each battery module (like 110, 120, and 130) has several individual battery cells (for example, 112, 114, 116, 132, 134, 136, etc.). The number of battery modules and cells in a pack can be different depending on what the device needs. A battery pack might have one, two, three or more battery modules, and each battery module may include one, two, three, or more cells based on the design of the device. Each individual battery cell may be made up of several important parts, such as cathode, anode, separator, electrolyte, and battery case.

### Battery Management System

The BMS 104 monitors the battery apparatus' performance. As illustrated in FIG. 1, the BMS 104 may include an interface 106 and a processor 108, designed to receive and process important data for the battery. The BMS monitors several key parameters such as the state of charge (SOC), voltage, Open-Circuit Voltage (OCV), current, and temperature of the battery. This data is vital for maintaining the health of the battery, enhancing its safety, and ensuring optimal energy management. The BMS 104 can be integrated directly into the battery and/or manage it remotely. It gathers data that provides information regarding the battery's performance and safety. By using one or more processors, the BMS can control different components, perform calculations, and transmit diagnostic results to external devices like cloud servers or user terminals for further analysis. The BMS monitors and evaluates the battery pack's status either directly or indirectly. In some embodiments, the BMS 104 identifies any abnormalities within the battery pack 102 by analyzing OCV data obtained from the battery unit. When irregularities are detected, the BMS can trigger an alarm, which may include visual, audio, and/or haptic notifications. The term “battery unit” refers to components such as the battery pack, individual battery modules, and battery cells. In some cases, the BMS 104 may be integrated within the battery unit itself as part of a larger system. Alternatively, the BMS 104 can operate separately from the battery unit, functioning as an external server connected via a wireless network.

### Another Example Electronic Device

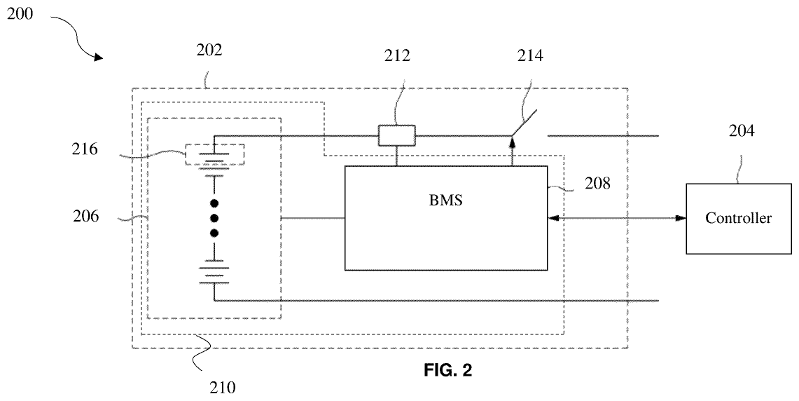

FIG. 2 illustrates another example of an electronic device 200 that includes a battery system 202 and a controller 204, which work in harmony to ensure efficient functionality and safety. The controller, also called the electronic control unit (ECU) or module (ECM), acts like the brain of the device. It can be used to manage and coordinate all the components inside an electronic device. It may communicate directly with the battery system 202 to control how the power flows, making sure the device gets the right amount of energy when needed. The battery system 202 may include a battery module 206, a Battery Management System (BMS) 208, a sensor unit 212, and a switching unit 214, which work together to keep the device running smoothly. In some instance, the device may include multiple battery modules 206, sensor units 212, switching units 214, and BMS 208. The BMS 208 shown here may be the same as or different than the BMS 104 shown in FIG. 1, and the battery module 206 may be the same as or different from the battery modules 110, 120, or 130 in FIG. 1. These reference numbers can be considered as a way to connect different parts in the pictures. The way these parts are arranged in the figures is for illustration and is non-limiting.

### Sensor Unit

The sensor unit 212 may be equipped with various sensors, such as current sensors, voltage sensors, and temperature sensors, each responsible for monitoring different aspects of the battery's performance. The current sensors measure the flow of electricity into and out of the battery during both charging and discharging cycles. These sensors may take measurements at regular intervals, such as during charging (when the battery is being replenished with power) and discharging (when the battery is powering the device), and can measure each datapoint at a single measurement timeframe. The data collected is sent to the BMS for analysis, providing critical real-time information on the battery's performance. Voltage sensors, placed in parallel with the battery, monitor the voltage across the battery terminals. The voltage sensor generates a voltage signal, which represents the battery's voltage level. This information may be crucial for ensuring the battery's proper functioning and safety, as any significant changes in voltage can indicate potential issues that need to be addressed. These sensors provide comprehensive data that allows the BMS to effectively monitor and/or manage the battery's health and performance, ensuring safe and efficient operation.

### Switching Unit

The switching unit 214 may be connected to the battery module 206 at either the positive (+) or negative (−) terminal. This unit controls the flow of charge and discharge currents within the battery system. The BMS 208 manages the ON/OFF operation of the switching unit 214, which may be implemented as a relay or contactor. The switching unit 214 may be integrated with the battery module 206, allowing the BMS to monitor the battery's performance. By controlling the switching unit 214, the BMS 208 can regulate the current flow during both charging and discharging cycles, ensuring that the battery operates optimally and safely. This setup enables the BMS to accurately measure the OCV of each individual battery cell. These precise measurements are essential for evaluating potential fire risks and identifying abnormal conditions, such as short circuits or internal failures.

### Open Circuit Voltage Data Acquisition

The OCV is measured between the two terminals (the positive and negative ends) of a battery. The OCV indicates how much charge is left in the battery and whether the battery is in good shape. How OCV changes over time can indicate problems of the battery, such as short circuit or aging of the battery. For devices like electric cars (EVs) or portable electronics, keeping track of battery health is important because it affects how well the device works and how safe it is to use. In the electronic device illustrated in FIG. 2, the BMS 208 obtains OCV data directly from the battery cells 216. The sensor unit 212 measures important parameters, including the OCV data. The sensor unit 212 may also include communication circuits, which send the data to the BMS 208, through wires or wirelessly.

### Fire Risk Detection Based on OCV Drop Over Shorter Term

The OCV drops within individual battery cells may be observed with time. By comparing the OCV drop of a single cell with the average OCV drop across a battery apparatus including this single cell over a relatively short duration of time, it is possible to identify abnormal drops that are sharp and/or sudden, indicating potential underlying issues of the battery apparatus, such as short circuits or battery failures. These abnormal voltage drops are key indicators of potential fire hazards. They can be closely monitored, allowing early detection of problems that could compromise safety. This proactive approach may help prevent catastrophic events and enhance the overall reliability of the battery system.

### Fire Risk Detection Based on OCV Drop Over Longer Term

However, abrupt OCV drops over a relatively short duration of time may not capture all the potential risks. Investigations into fire incidents have shown that long-term monitoring, which captures more gradual, gentle OCV declines, can also reveal early warning signs of fire risks. A slow or moderate decrease in voltage over time may not trigger alarms in a short-term OCV monitoring system but could still indicate underlying issues that could eventually lead to fire.

### Fire Risk Detection Based on Combination of OCV Drops

This disclosure provides a method that combines two types of OCV drops—steep, short-term drops and more gradual, long-term declines—to identify fire risks. Although the slower, gradual voltage drops that happen over a longer period are harder to notice, they may indicate hidden issues that may be missed otherwise. By paying attention to the combination of voltage changes, the method provided herein offers an effective approach for early battery fire risk detection, catching both immediate threats and subtle risks, making the battery apparatus safer and more reliable.

### Battery OCV Analysis

### Battery Cell OCV Measurement Example

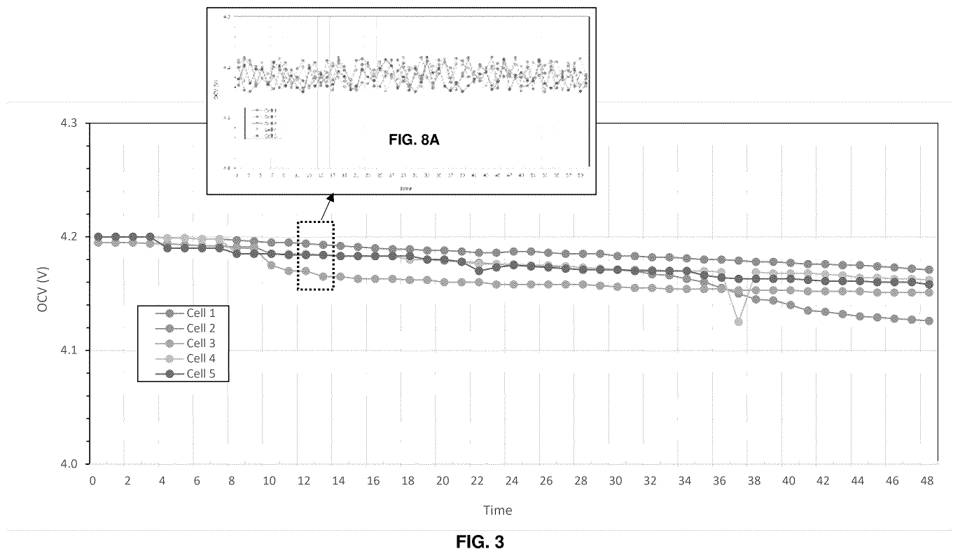

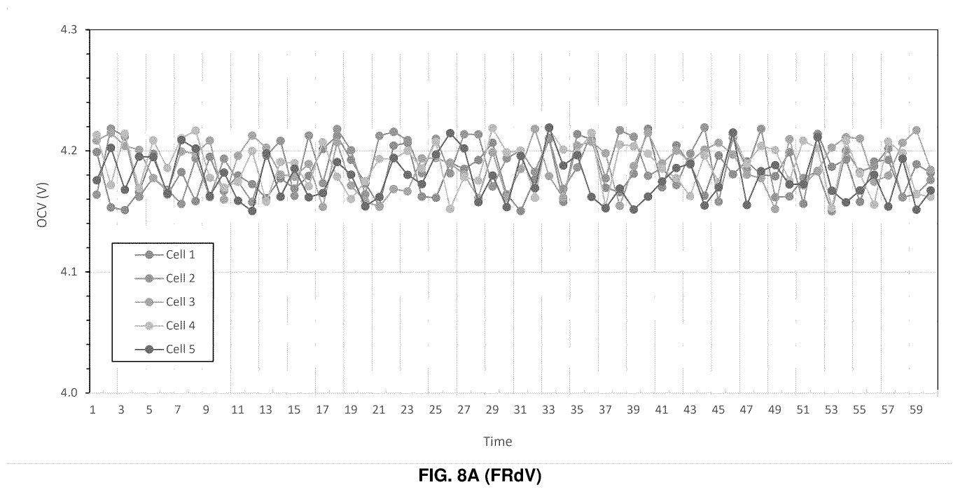

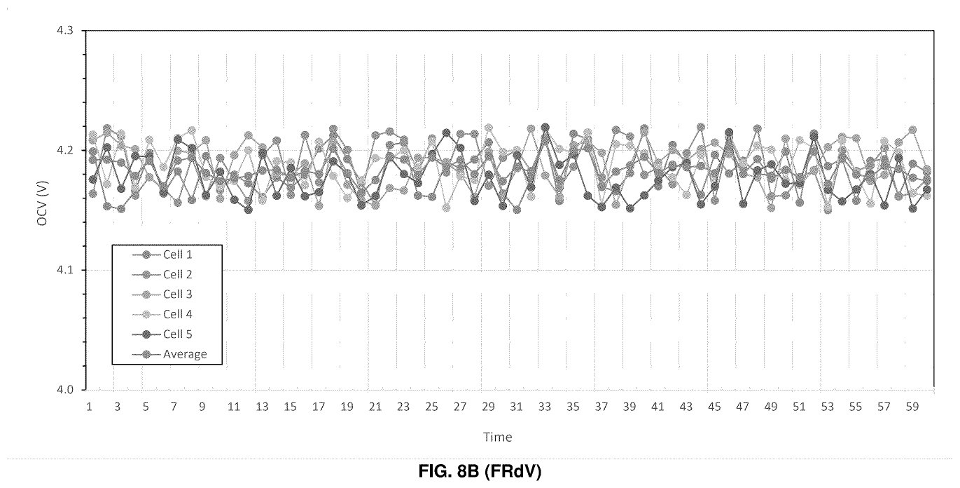

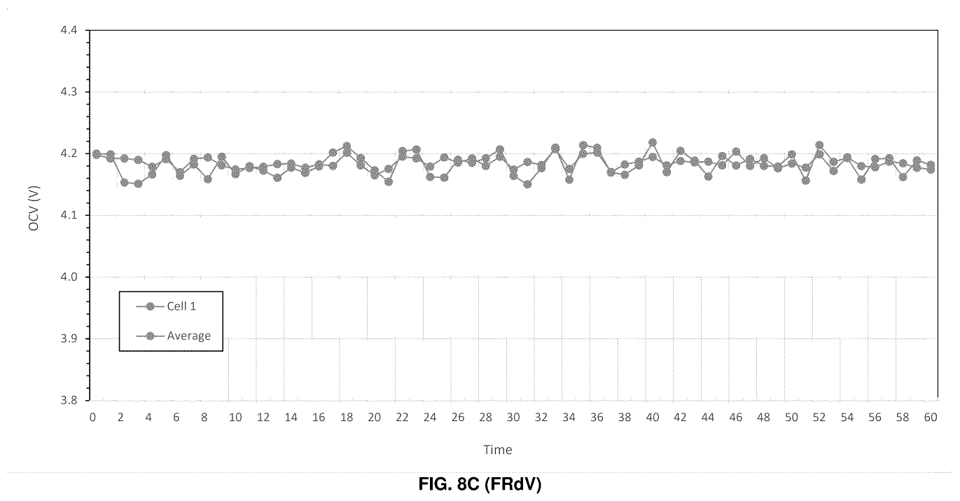

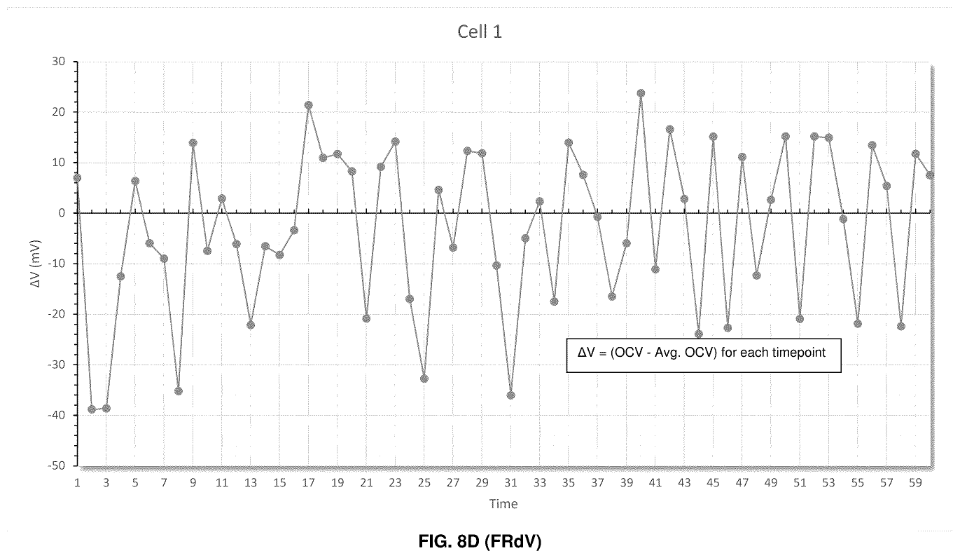

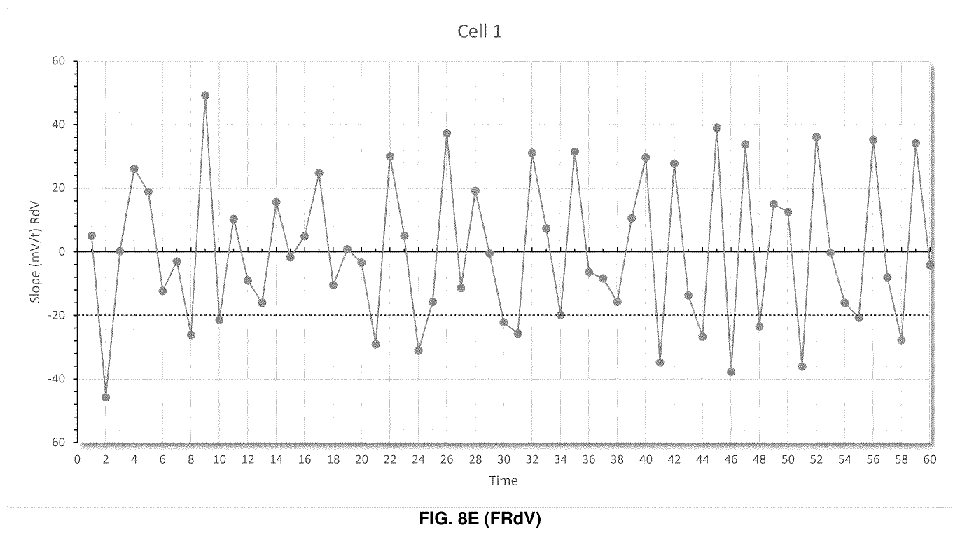

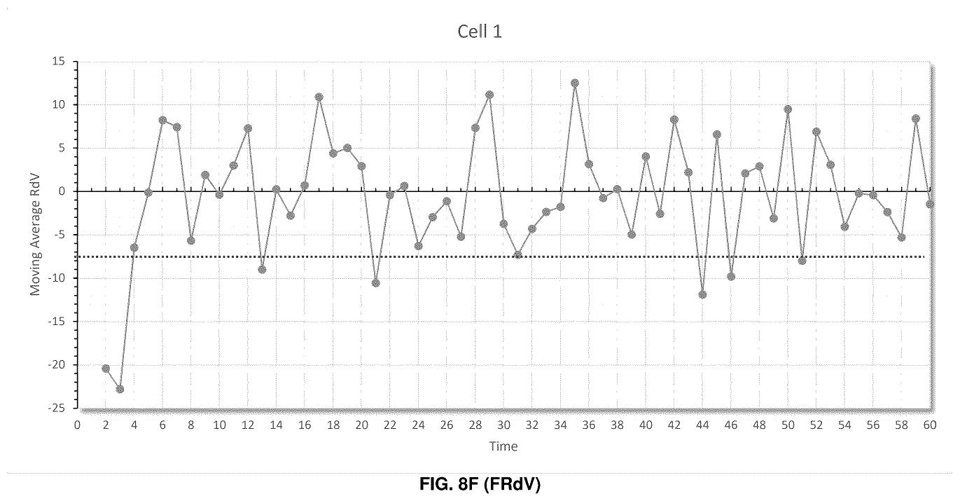

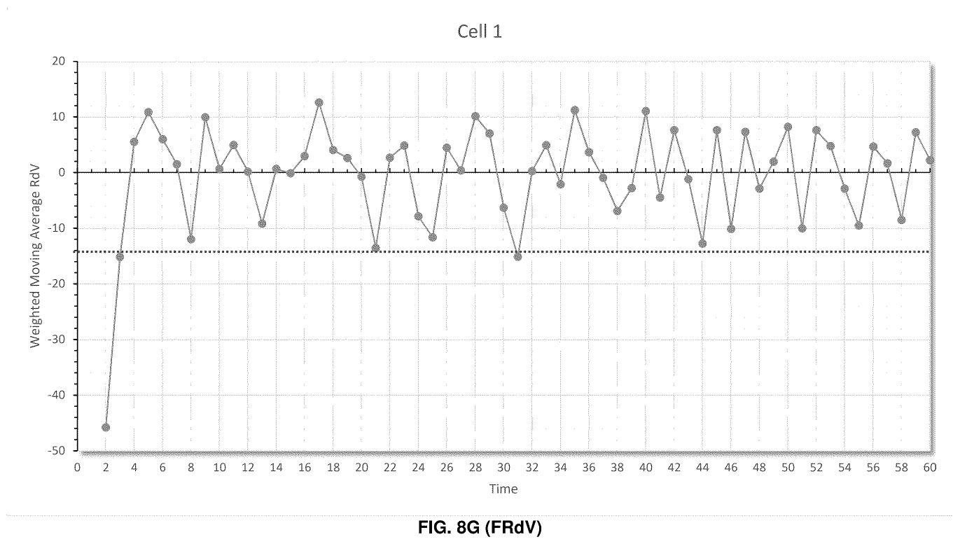

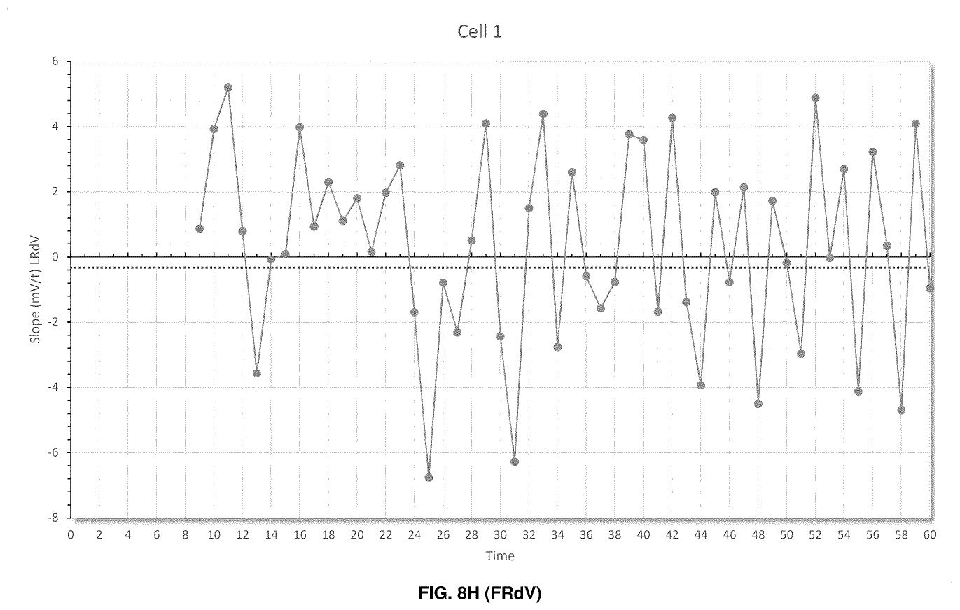

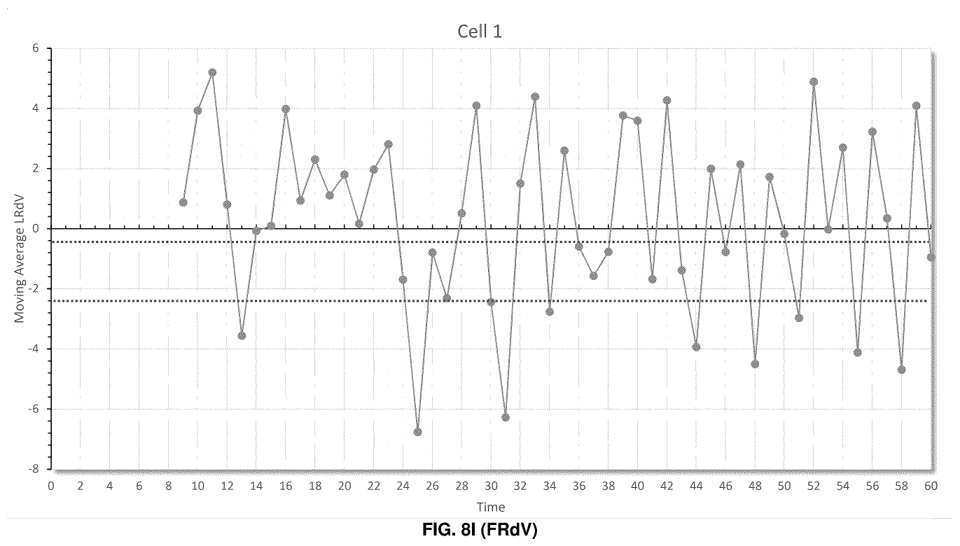

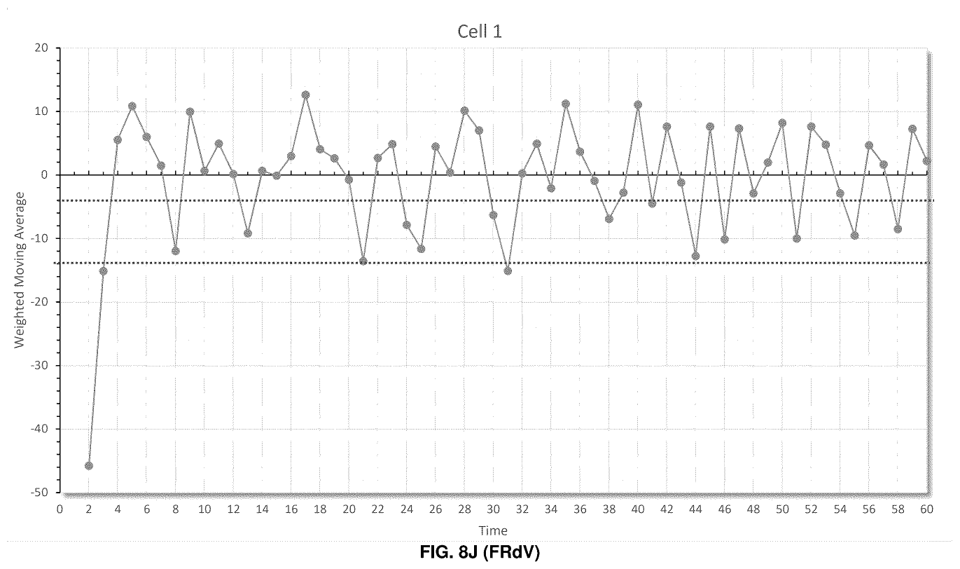

In FIGS. 3-8J, example OCV values of five example battery cells in one example battery module are measured. As mentioned earlier, the OCV tends to go down over time. In these examples, the measurements are repeatedly taken over a period of 48 units, which can be months in some embodiments, to provide multiple sets of voltages for the plurality of battery cells. This time frame is just an example for illustration and can be shorter or longer. The measurements may be taken once a month, and it can be on the first day, the second day, the last day of the month, or any other day of the month. The measurement can be taken on the same day each month and/or on different days in different months. The frequency of the measurements can vary. Instead of once a month, the measurements can be taken more often or less often, such as once every two months, once every three months, twice a month, three times a month, once a week, once every hour (or every 2 hours, every 3 hours, etc.), daily (or every other day, every 3 days, etc.), weekly (or every other week, every 3 weeks, etc.), or at any other frequency. For example, FIGS. 8A-8J show measurements taken more frequently than those shown in FIGS. 3-7Q, such as daily or hourly, which illustrate how taking measurements more often can be helpful and used in real life.

OCV Data from Battery Cells

FIG. 3 shows OCV data measured from the battery cells inside a battery module. These measurements are taken at regular intervals, such as daily, weekly, or monthly, over a duration of time units, which can be months, weeks, or days, etc. Each battery cell is measured multiple times at each interval, creating a detailed picture of how the battery is performing. In one embodiment, measurements are taken once a month over a span of 48 months. These measurements may occur on the first day of the month, the last day of a previous month, or any other selected day. The OCV values, or the power levels of the battery, are plotted on the vertical axis, with time on the horizontal axis. This figure shows that these example battery cells may initially lose power at a similar rate, but over time, their behaviors may start to differ. For example, cell 2 has the largest OCV drops as time goes by after 38 months, and cell 4 shows a noticeable large drop in power after about 37 months. The other cells, on the other hand, have slower and steadier drops over the whole 48 months. Further detailed data, with measurements taken more frequently, can be seen in FIG. 8A through FIG. 8J, which will be described in detail later.

### Averaging Data for Comparison

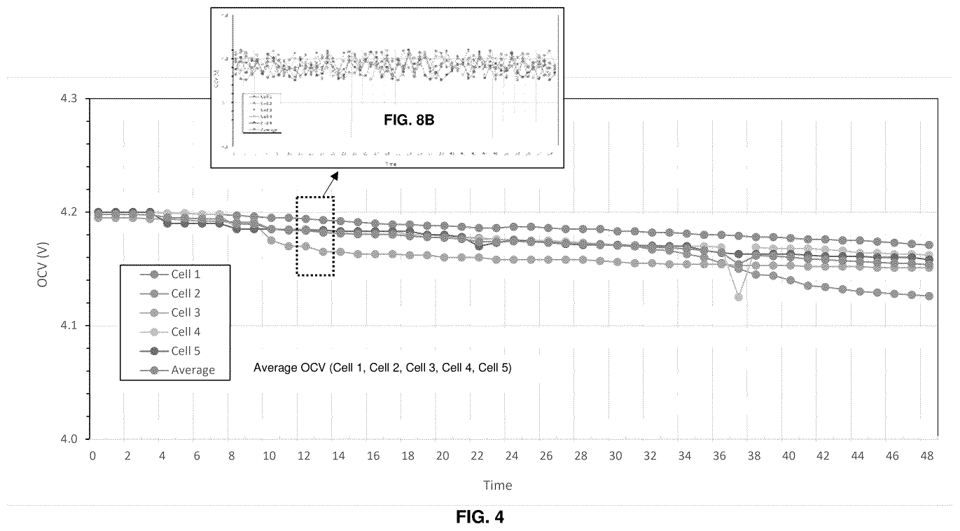

The measurements from the five cells are taken multiple times and then averaged at each measurement timeframe to create multiple composite voltages for the corresponding measurement points. This average value is shown in FIG. 4. The average serves as a reference to compare the power levels of each cell, making it easier to spot any unusual changes in the cells' performance. In addition, multiple composite voltages can be created for each of the five battery cells. Each composite voltage can represent the average voltage for the cells at a particular time. The power levels of each cell can be constantly monitored and compared to the average of all the cells. If any of the cells show a large difference from the average, the system may flag it as a possible problem.

### Short-Term Voltage Drop Analysis (RdV)

### Cell 1 OCV and Average OCV Comparison

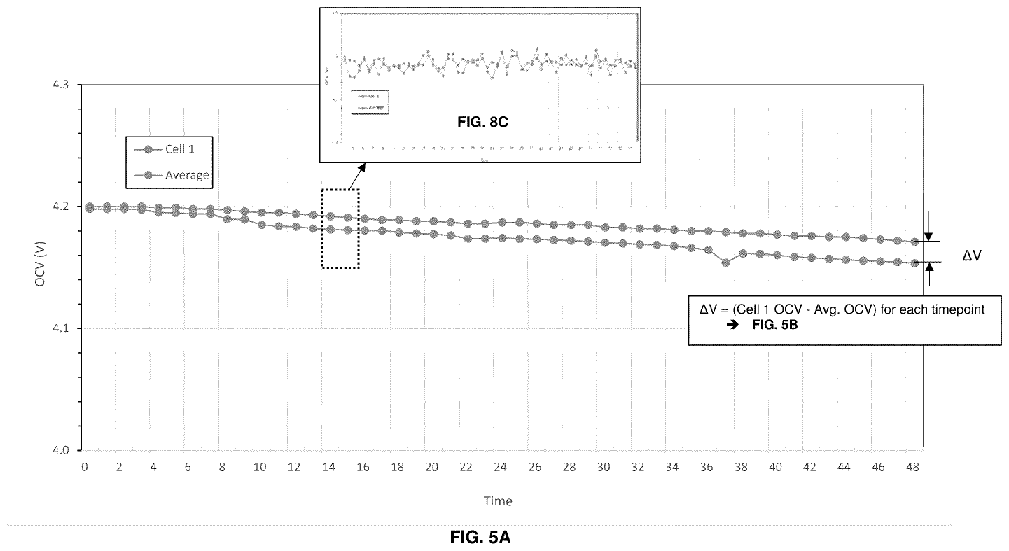

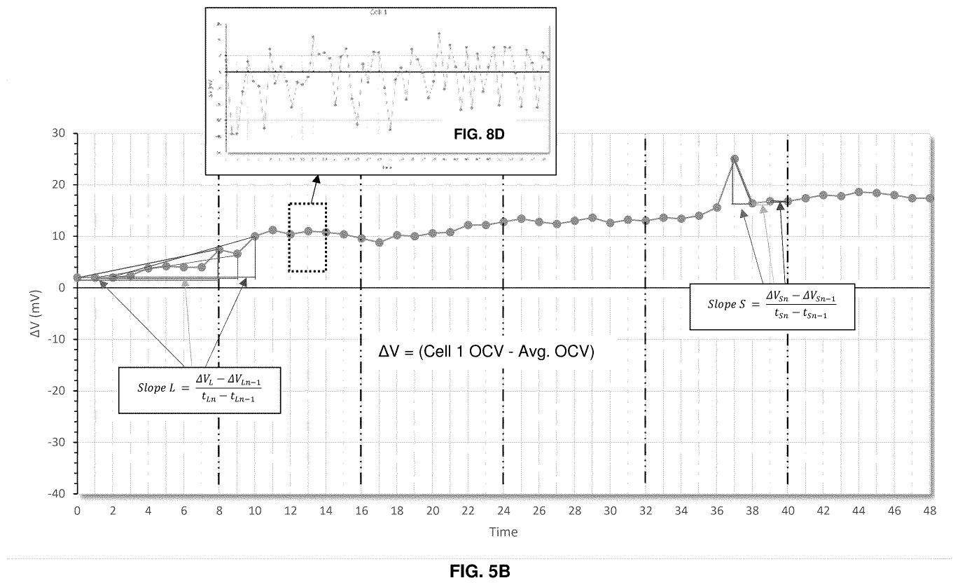

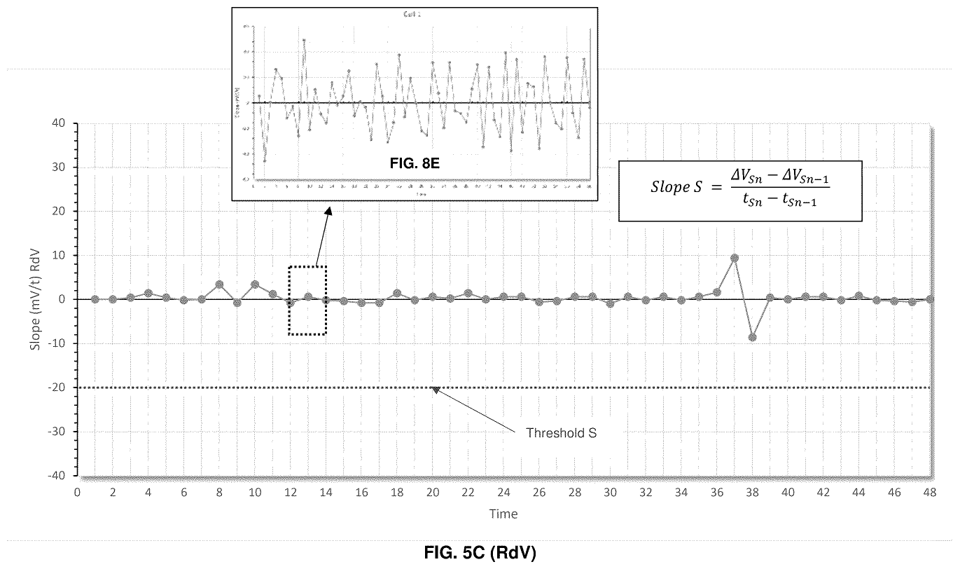

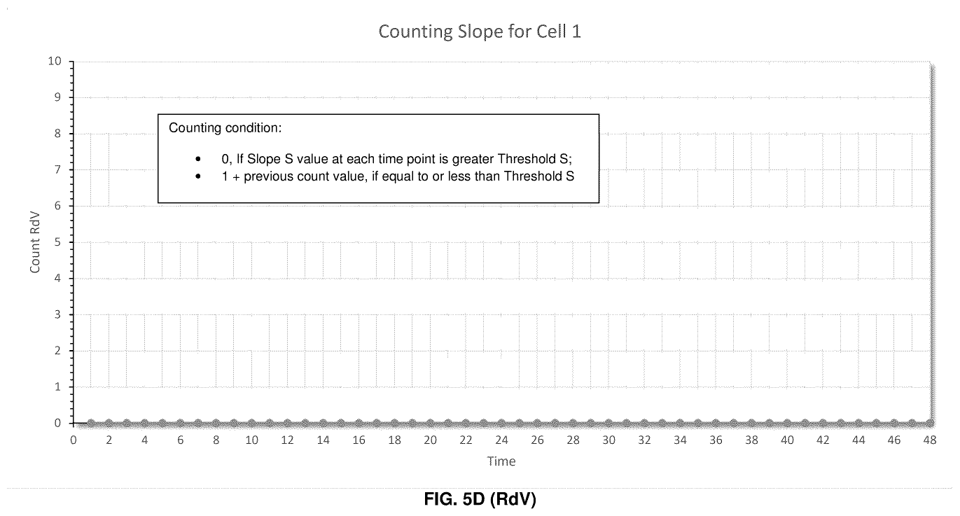

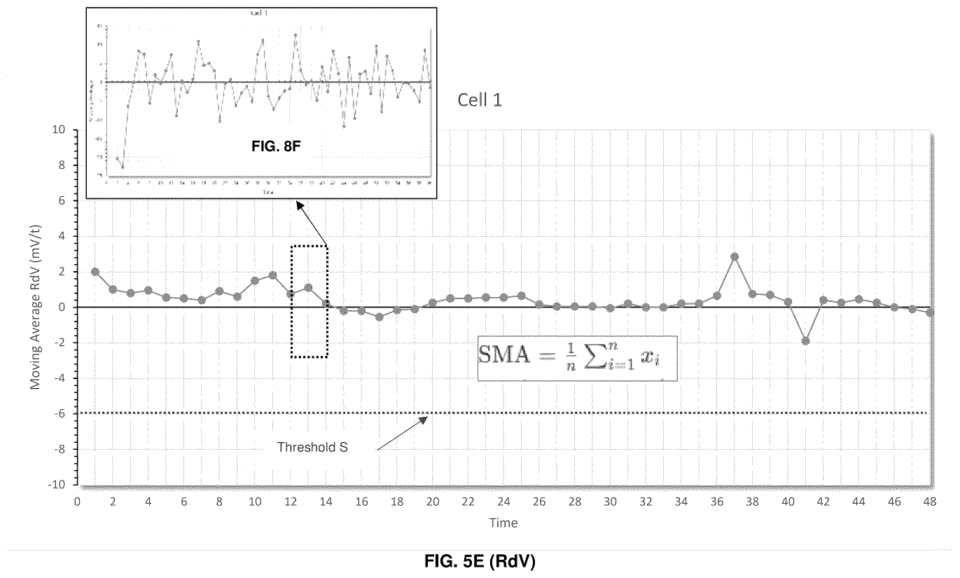

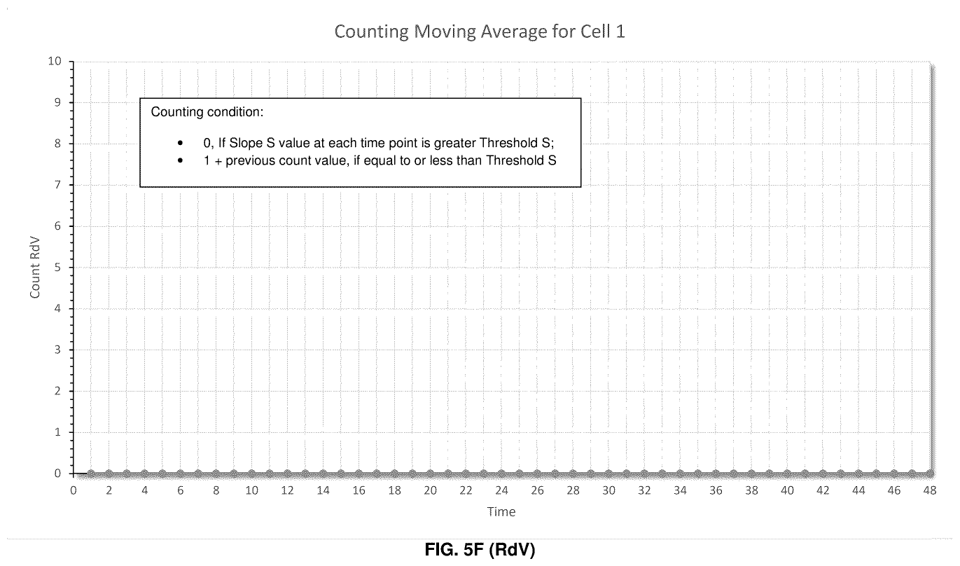

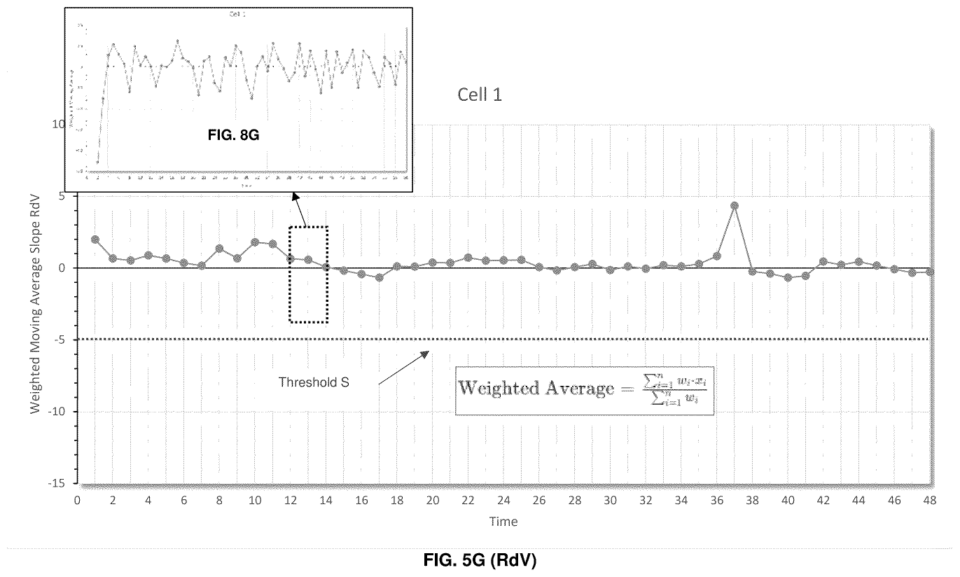

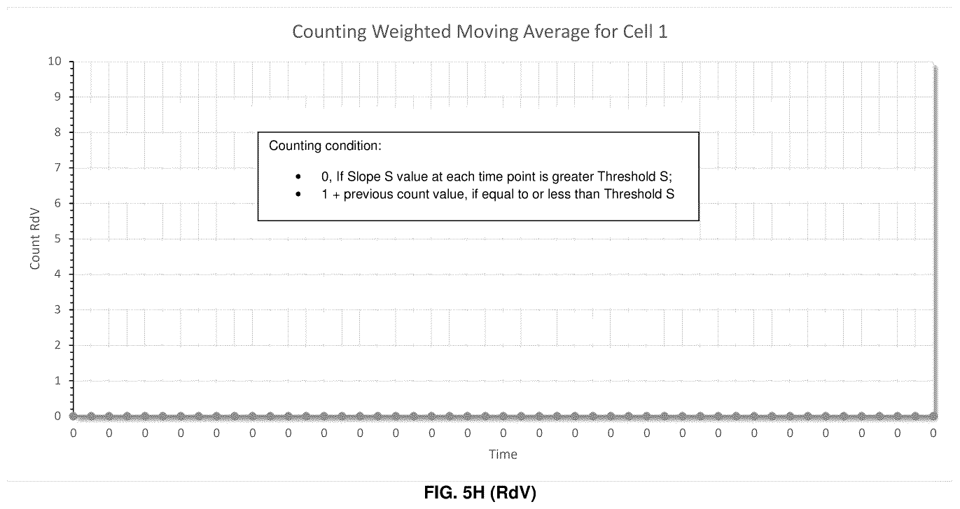

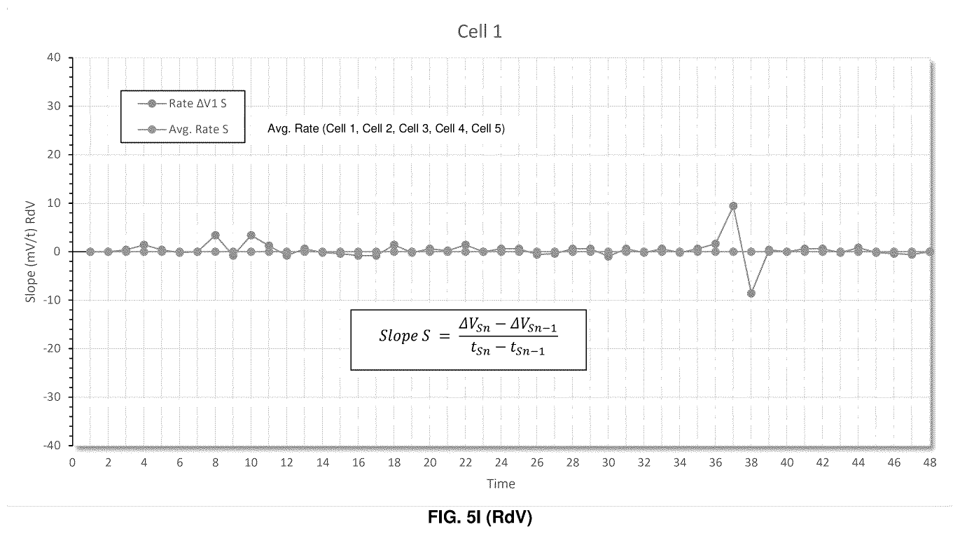

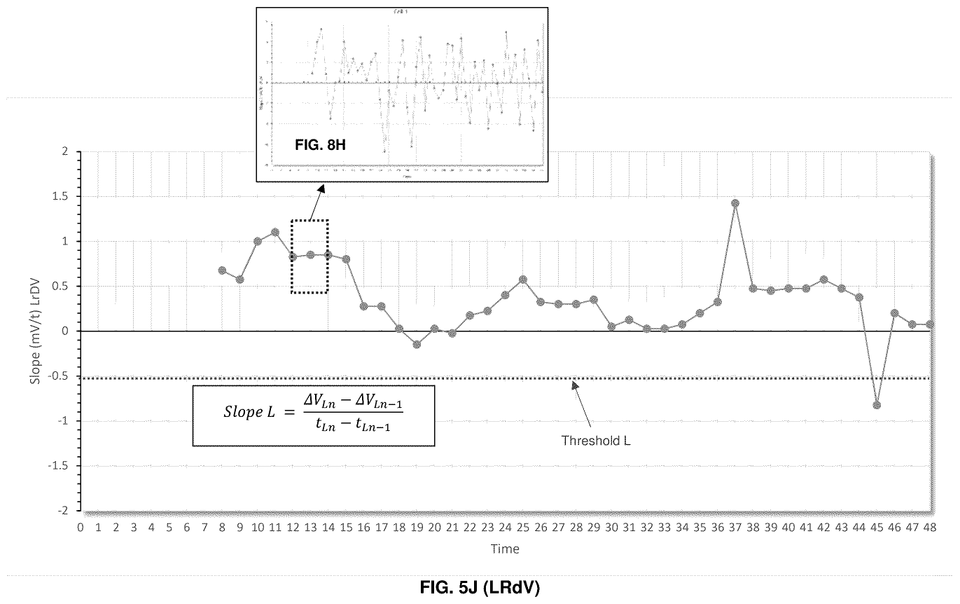

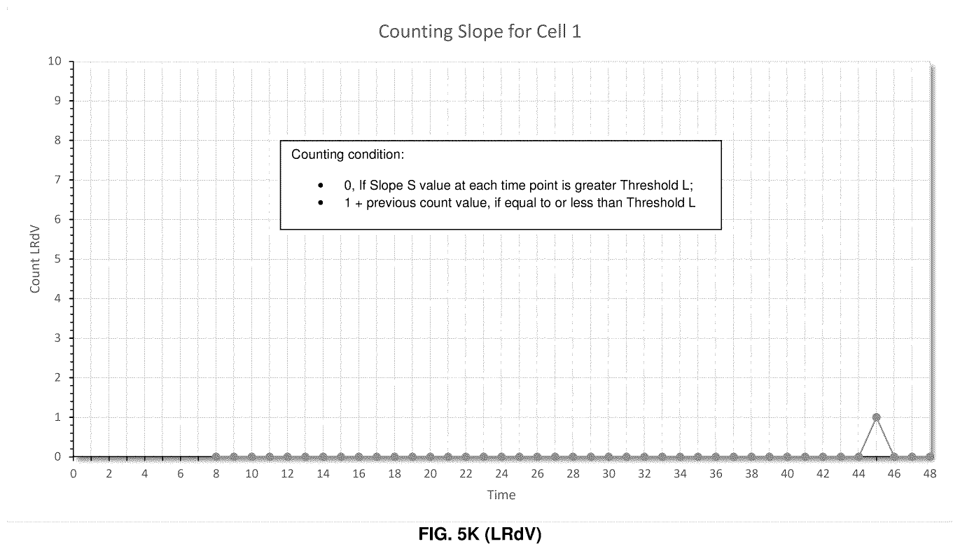

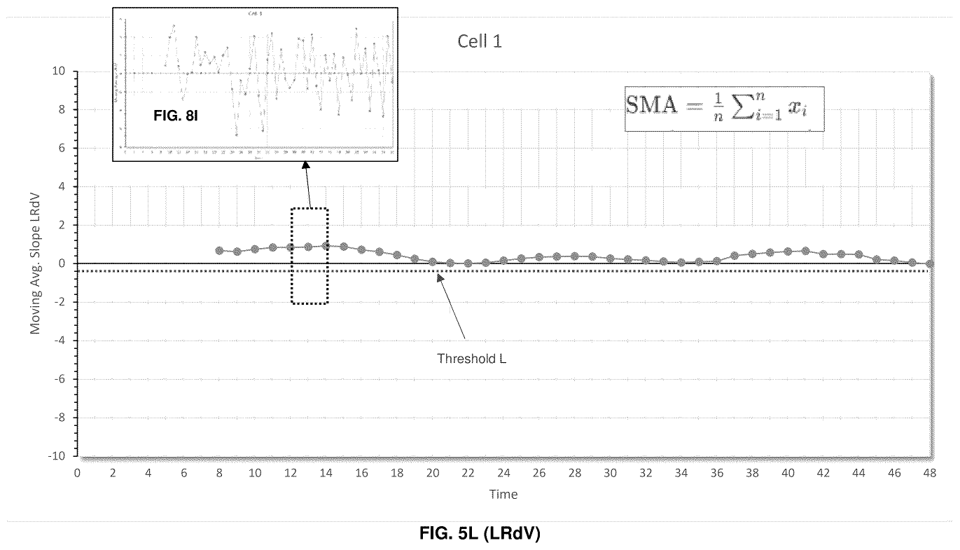

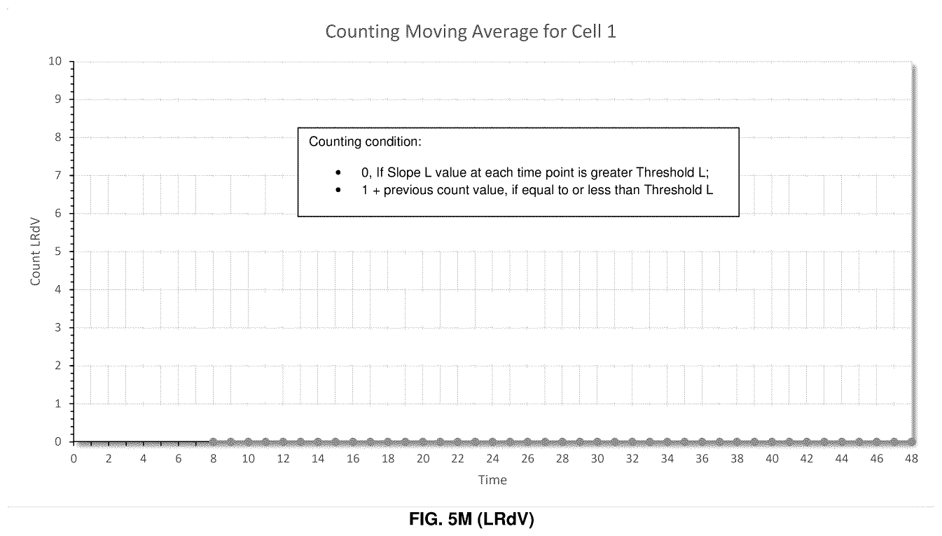

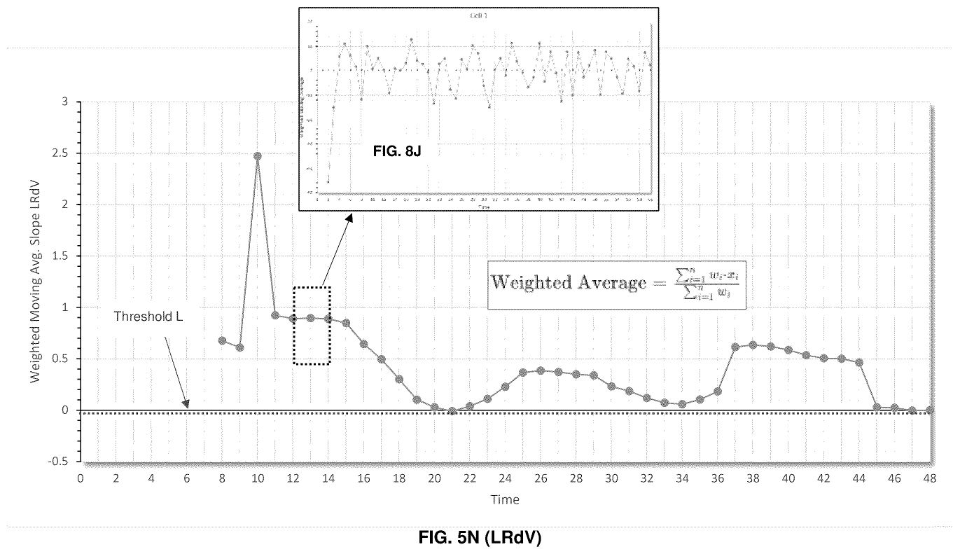

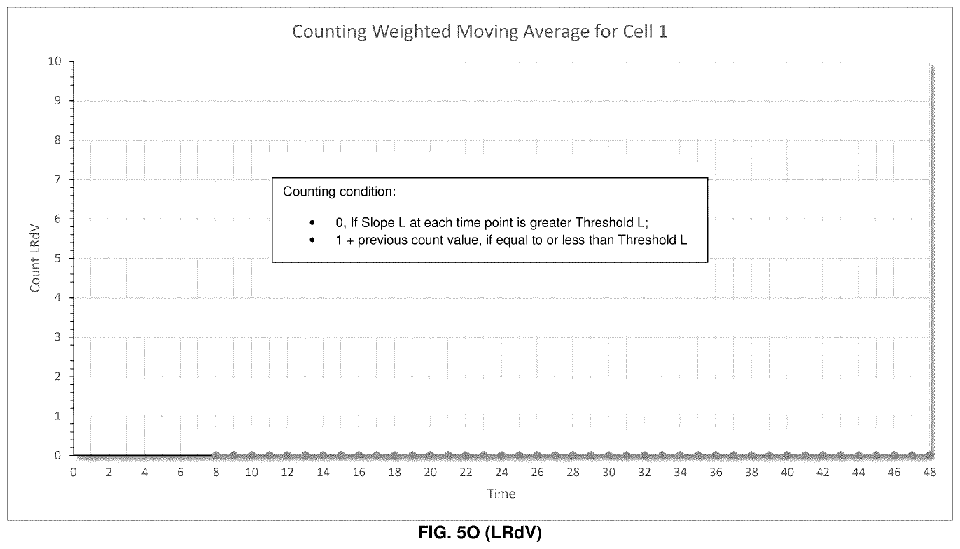

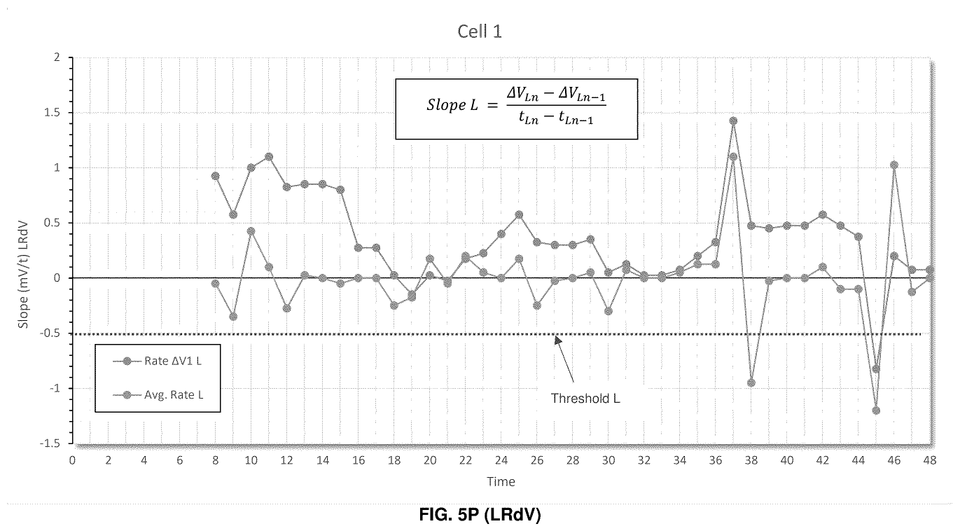

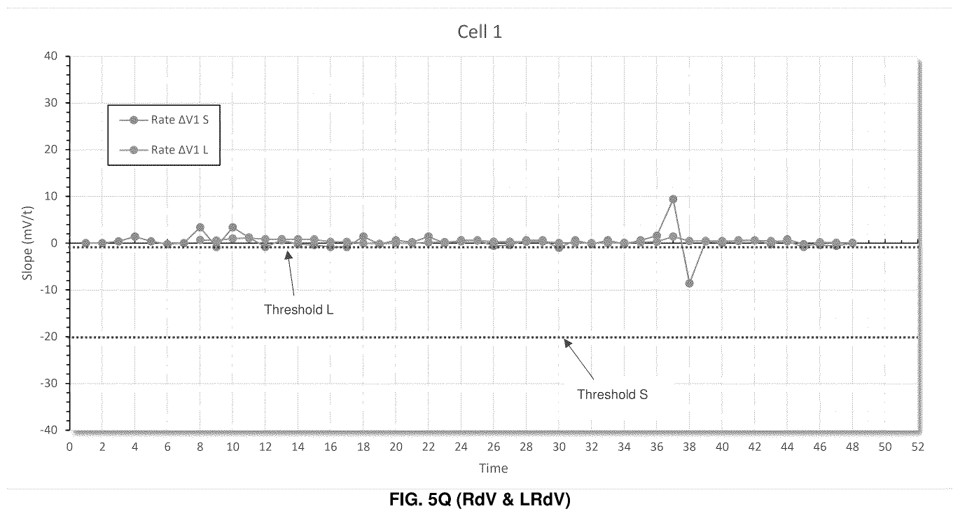

The process for detecting quick voltage drops involves looking at how the voltage of each battery cell compares to the average voltage of all the cells. FIG. 5A shows the OCV values of an individual cell (cell 1) and the average OCV values of all five cells over time. FIG. 5B shows the differences between the power levels of cell 1 and the average power levels of all five cells at each measurement time point, shown in FIG. 5A. At each time point when the OCV values of the cells are measured, the difference between cell 1's OCV and the average OCV of all cells is calculated as ΔV=OCV for cell 1−Avg. OCV. These ΔV values are plotted against the time units in FIG. 5B. For example, in FIG. 5A, at time point 18, the OCV for cell 1 is 4.189 V, and the average OCV for all cells is 4.1788 V. Thus, at time point 18, the ΔV is 10.2 mV, and the ΔV and time units are plotted in FIG. 5B. As another example, at time point 48, the OCV for cell 1 is 4.171 V, and the average OCV for all cells is 4.1536 V. Thus, at time point 48, the ΔV is 17.4 mV, and the ΔV and time units are plotted in FIG. 5B. Then, the rate of change (e.g., voltage decrease) in the OCV difference, ΔV, or the “slope” of the change in the difference over a predetermined length of time, is calculated. An example Slope S (for the shorter term/duration measurement) is determined by calculating the change in the difference between month 37 and month 38, month 38 and month 39, and so on, over a 1-month duration of time. For example, in FIG. 5B, at 37 time units (e.g., 37 months), the ΔV value is 25 mV, and at 38 time units (e.g., 38 months), the ΔV value is 16.4 mV. Thus, the Slope S for 37 to 38 time units is calculated by dividing the change in ΔV by the 1 time unit, i.e., −8.6 mV, which indicates the rate of change in the ΔV value over the duration of time from 37 time units to 38 time units (e.g., 1-month duration of time). Slope L (for the longer term/duration measurement) is calculated by looking at the change between month 0 and month 8, month 2 and month 9, month 3 and month 10, and so on, over an 8 or 7-month duration of time. For instance, in FIG. 5B, at 3 time units (e.g., 3 months), the ΔV value is 2.4 mV, and at 11 time units (e.g., 11 months), the ΔV value is 11.2. Thus, the Slope L for 3 to 11 time units is calculated by dividing the change in ΔV by the 8 time units, i.e., 1.1, which indicates the rate of change in the ΔV value over the duration of time from 3 time units to 11 time units (e.g., 8-month duration of time). If the slope of the change in difference is steep, meaning the difference is changing quickly, it can be considered an anomaly. This helps identify rapid voltage drops that might suggest problems, like overheating, damage, or other issues in the battery module.

### Cell 2 OCV and Average OCV Comparison

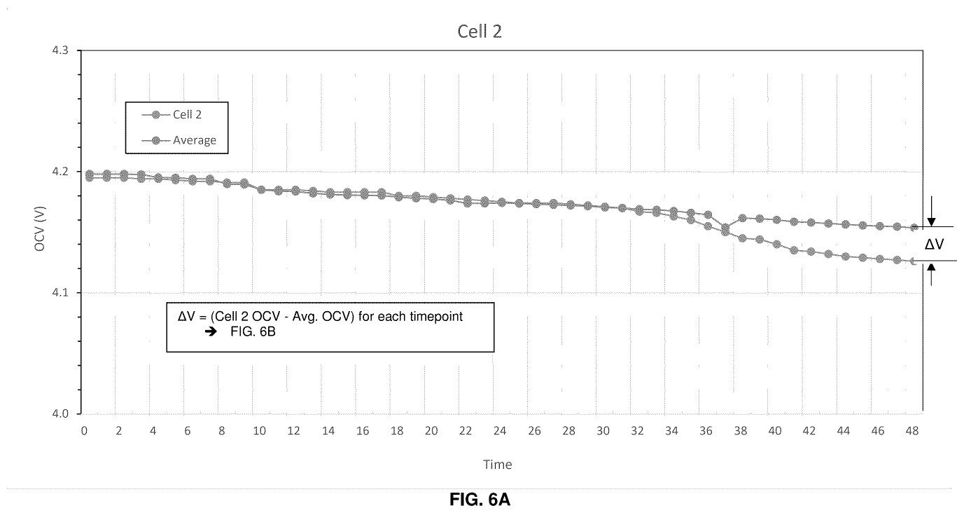

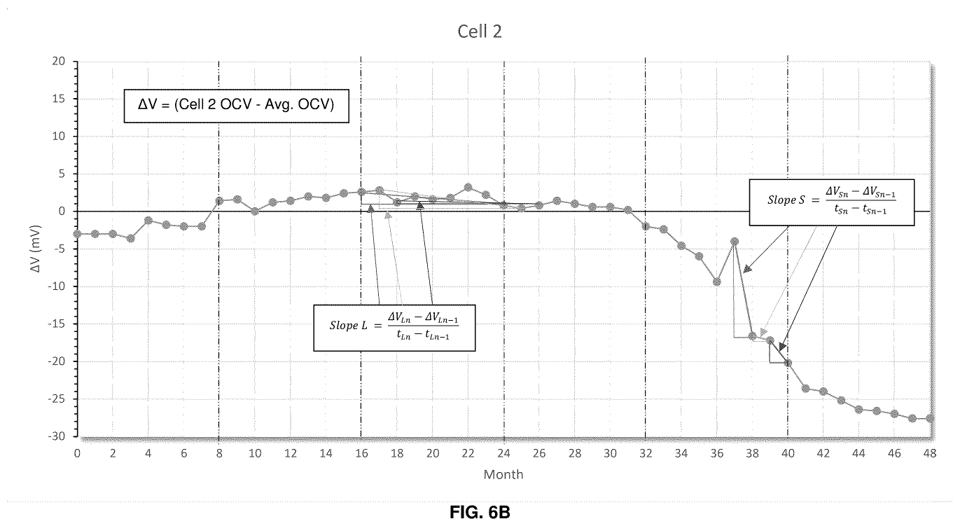

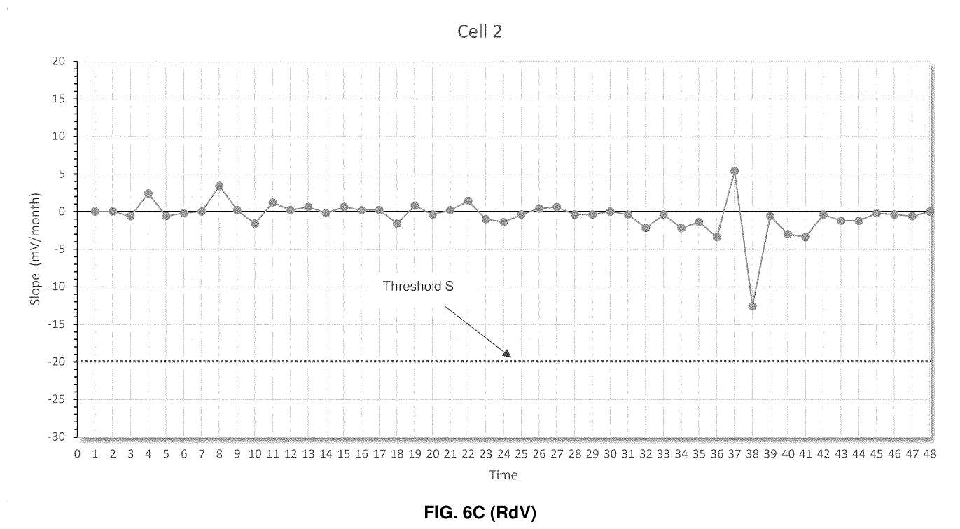

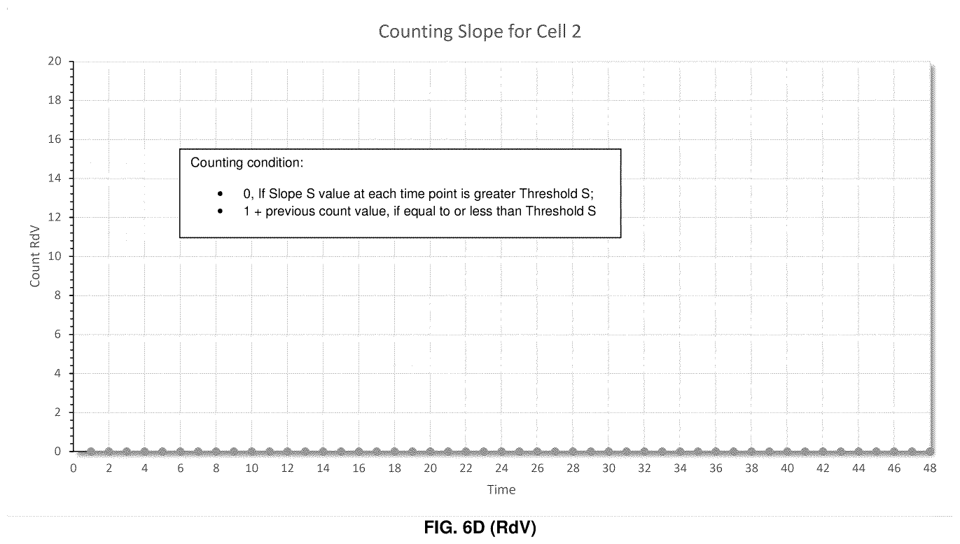

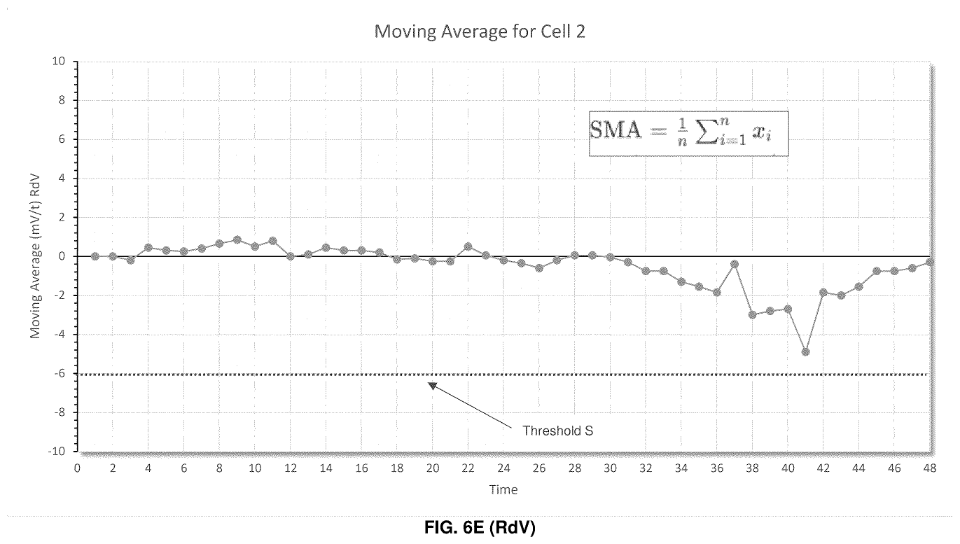

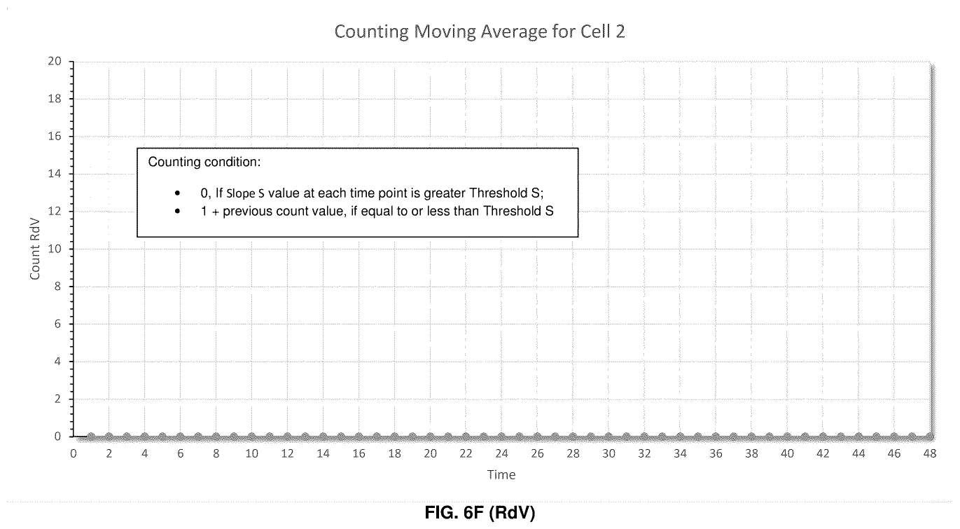

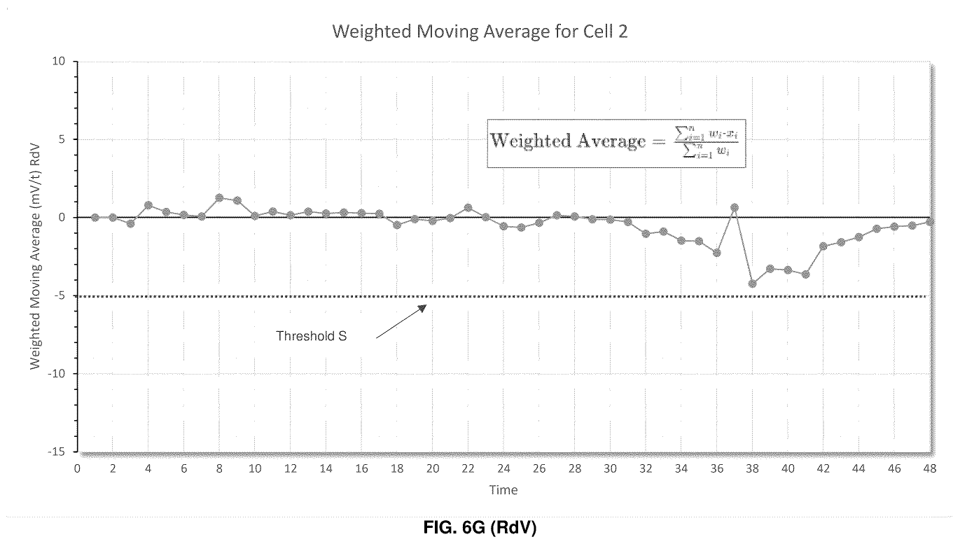

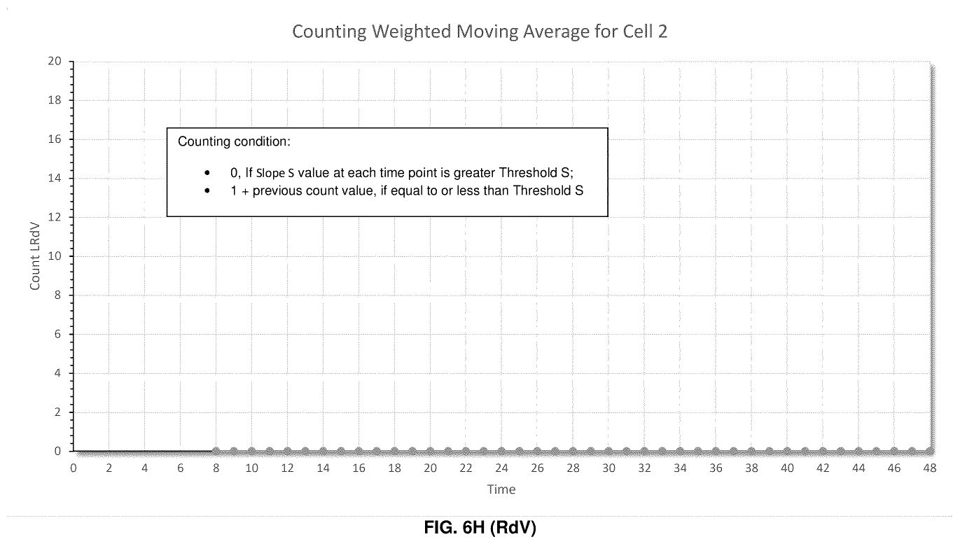

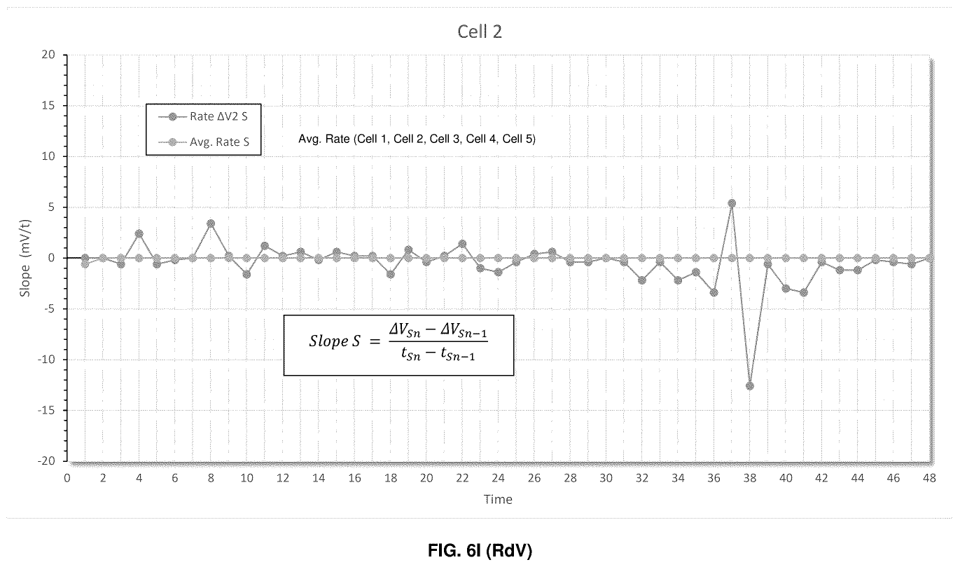

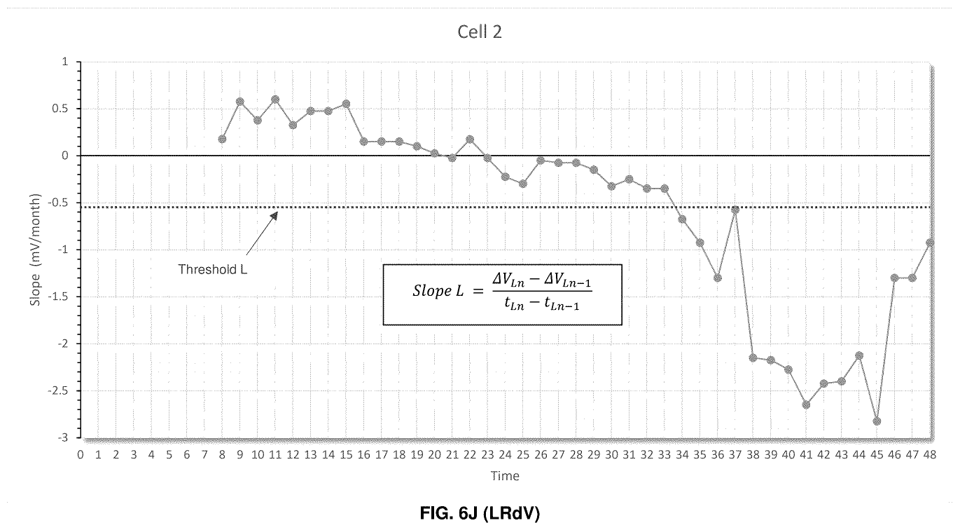

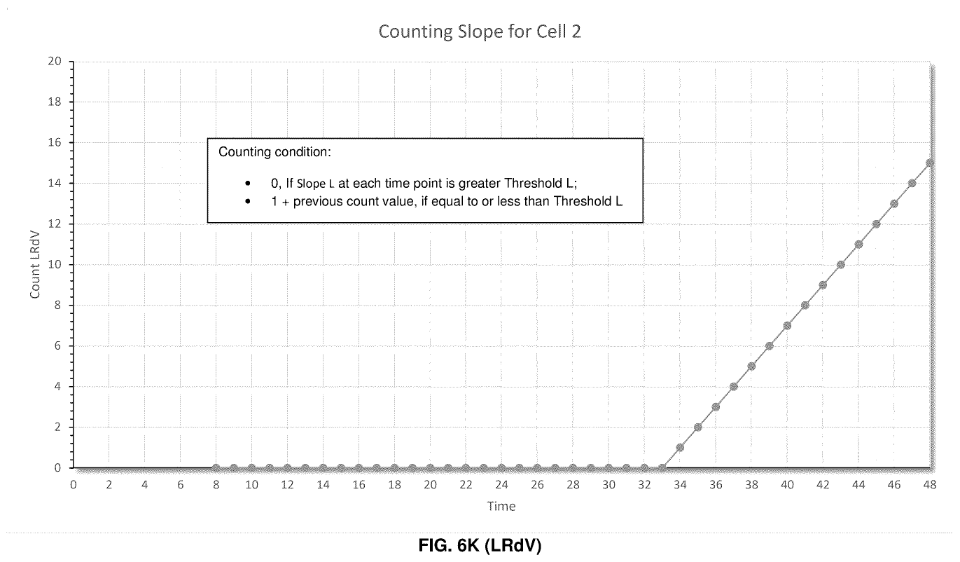

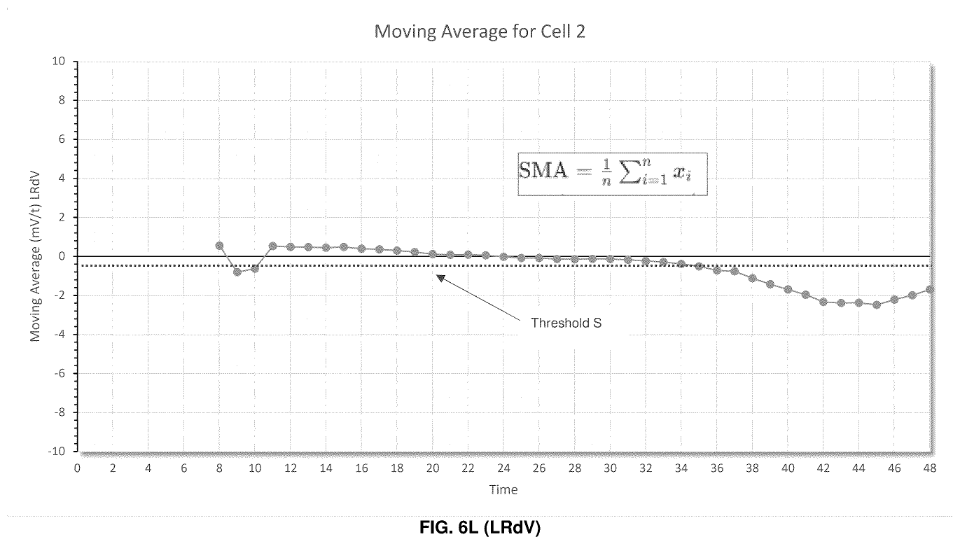

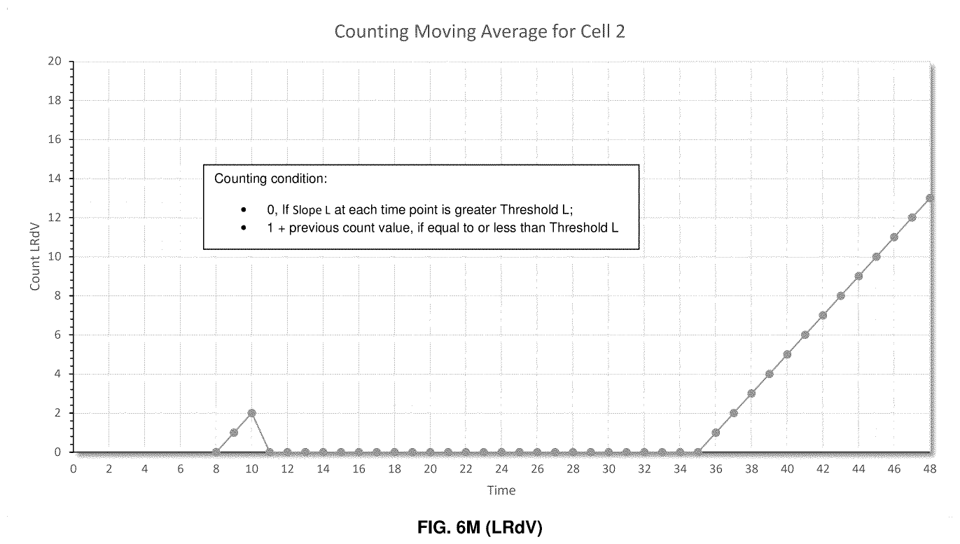

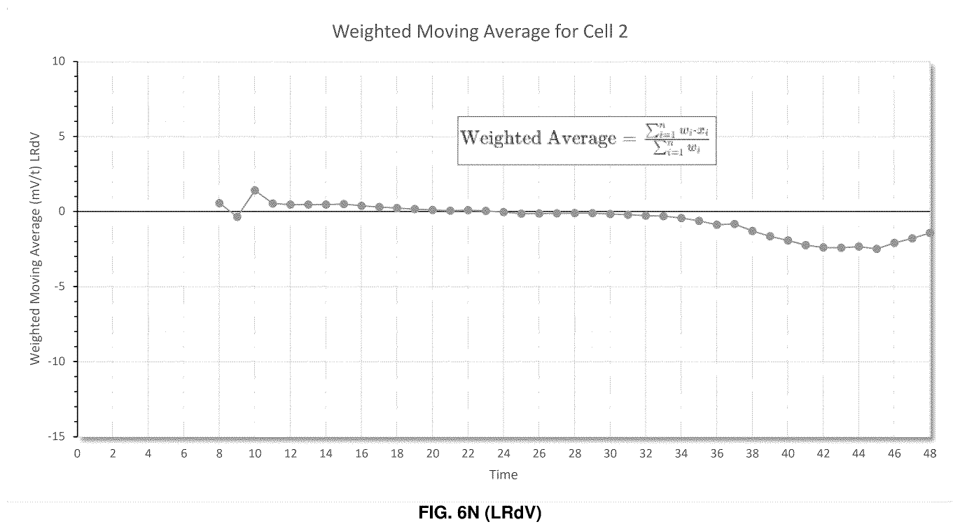

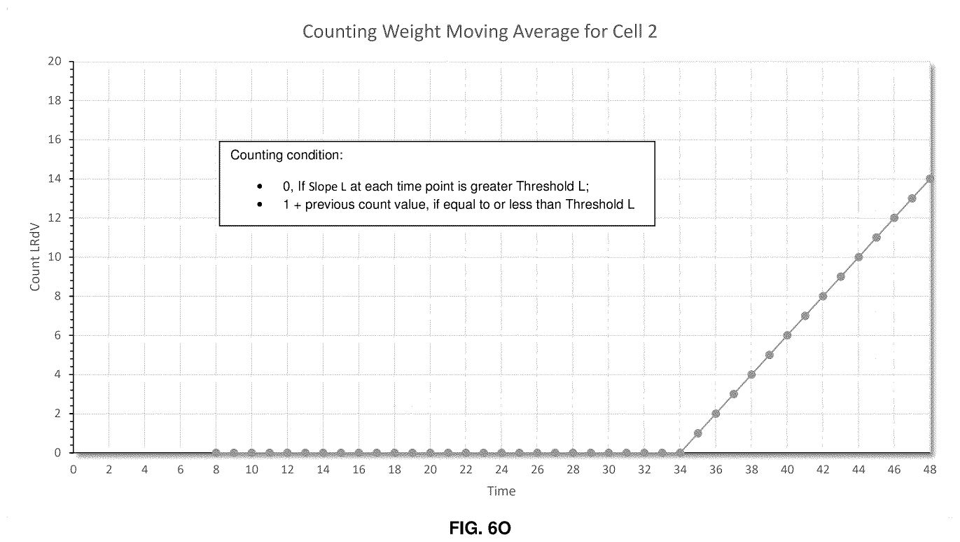

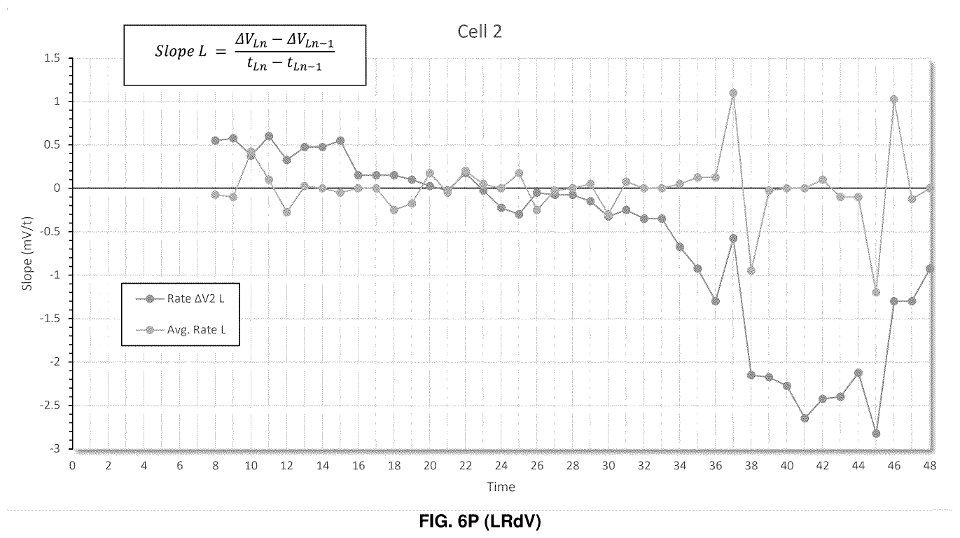

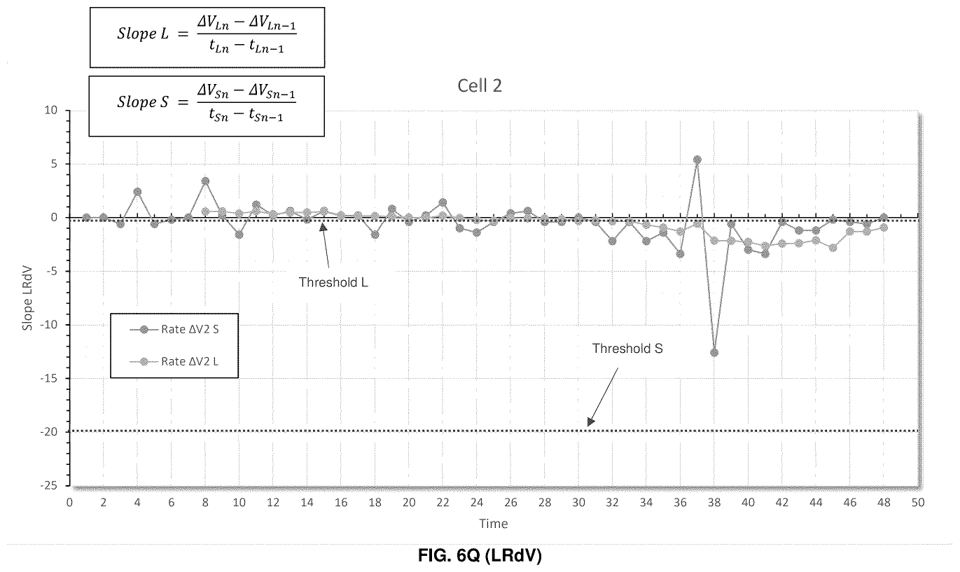

Similarly, FIG. 6A illustrates a comparison between cell 2 OCV values And the average OCV values of the five cells, and FIG. 6B shows the differential values (ΔV=OCV for cell 2−Avg. OCV) between the OCV values of cell 2 and the average OCV values of five cells at each measurement time point in FIG. 6A. These two graphs are similar to FIGS. 5A and 5B, respectively, but for cell 2, and therefore, the detailed description is omitted herein. In addition, similar to the slope calculation described for battery cell 1, an example Slope L is determined by the change in ΔV between month 16 and month 24, over an 8-month duration of time, and an example Slope S is determined by the change in ΔV between month 37 to month 38, over a 1-month duration of time.

### Cell 4 OCV and Average OCV Comparison

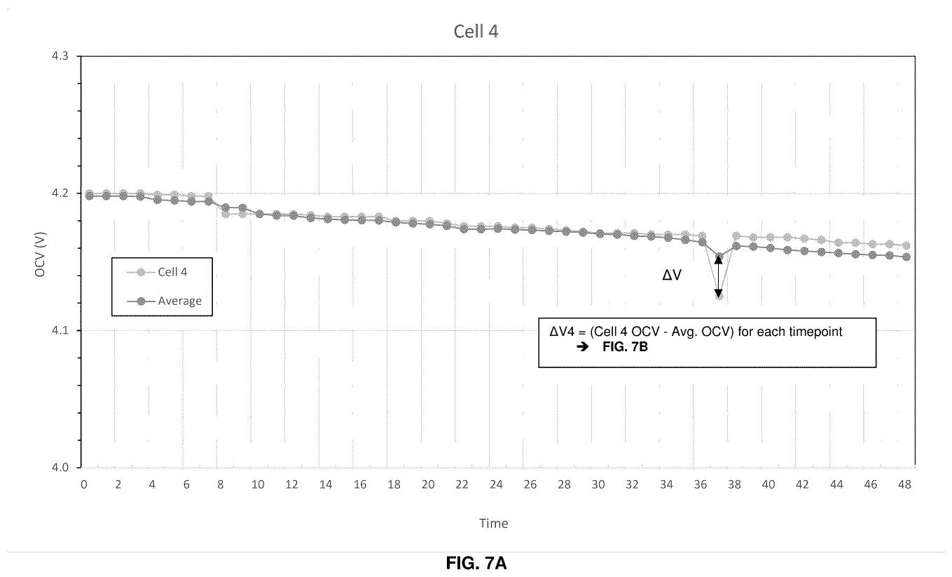

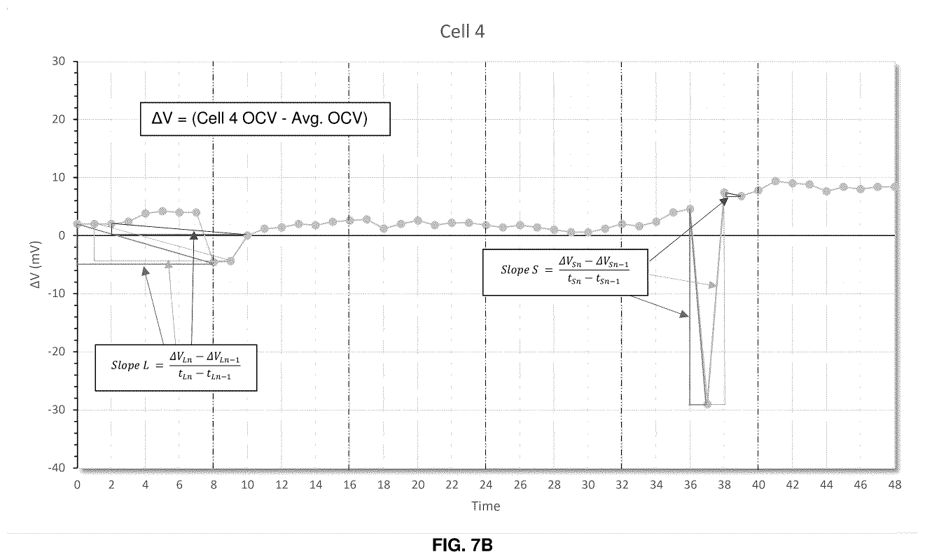

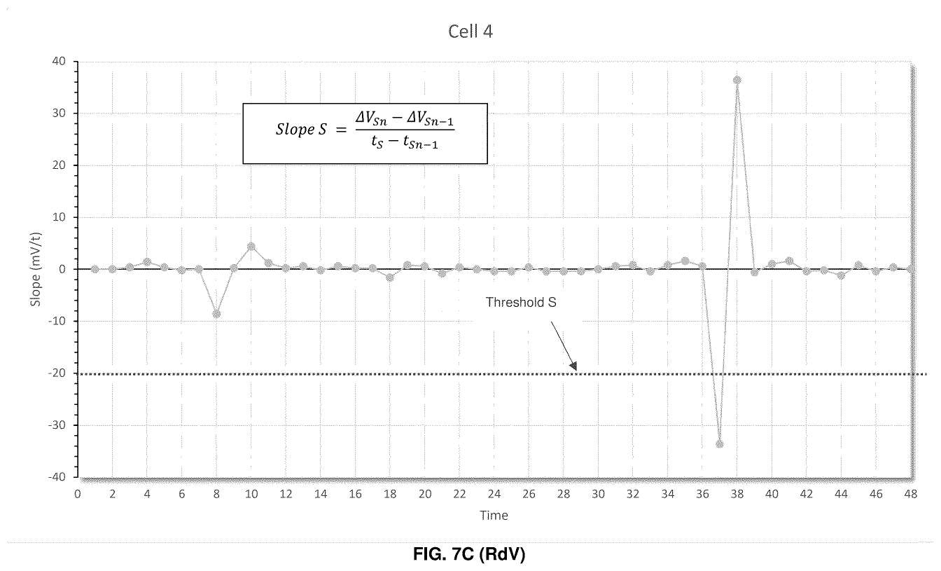

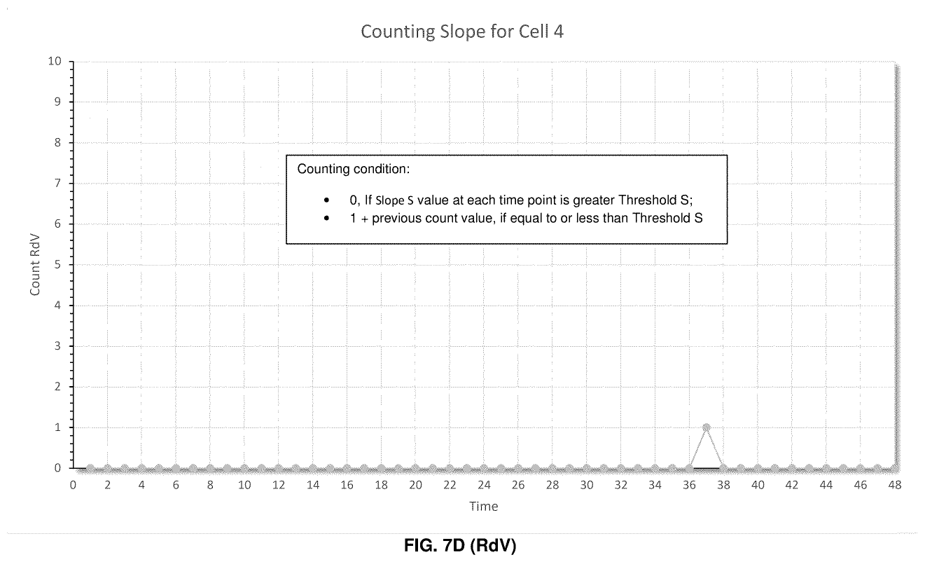

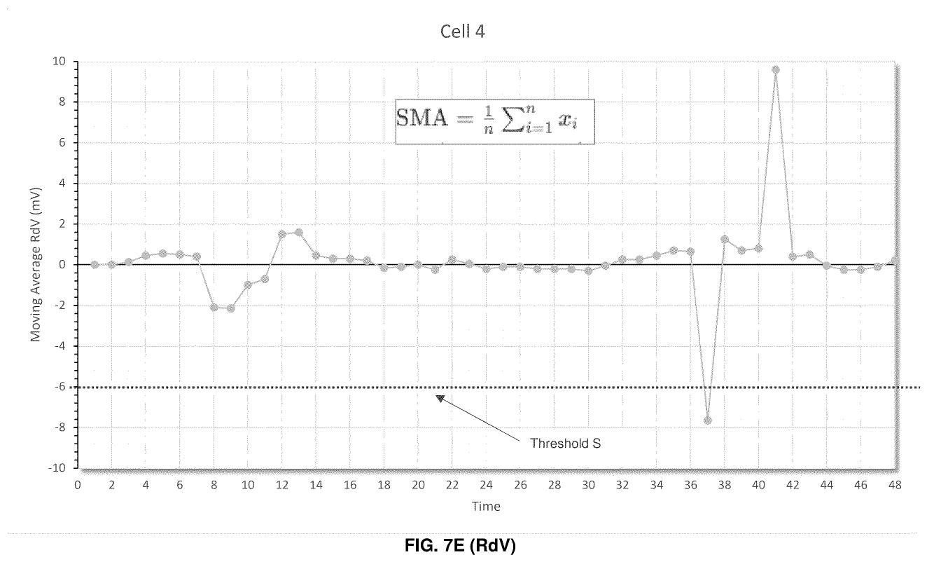

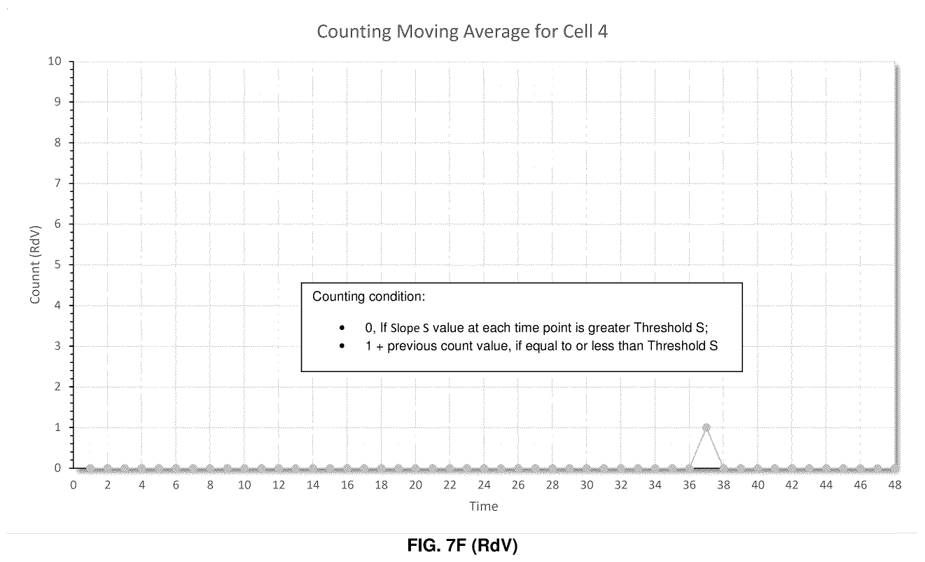

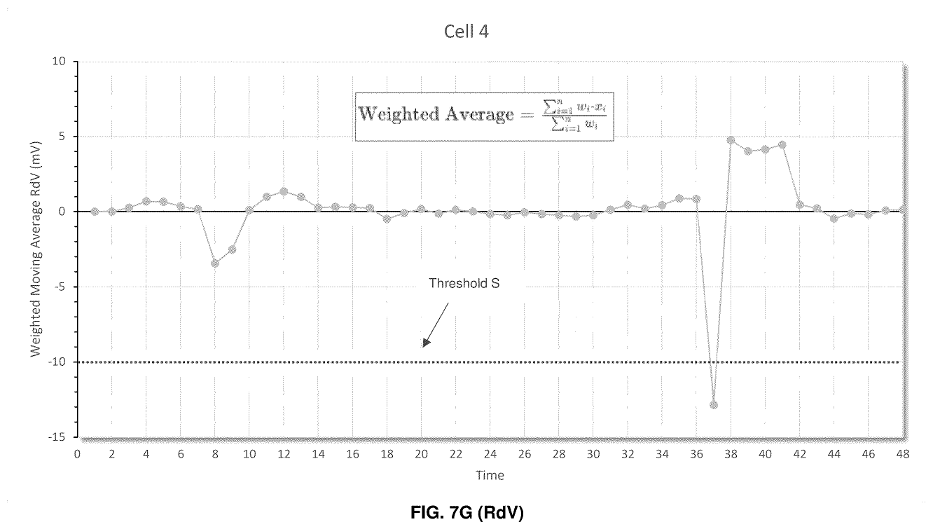

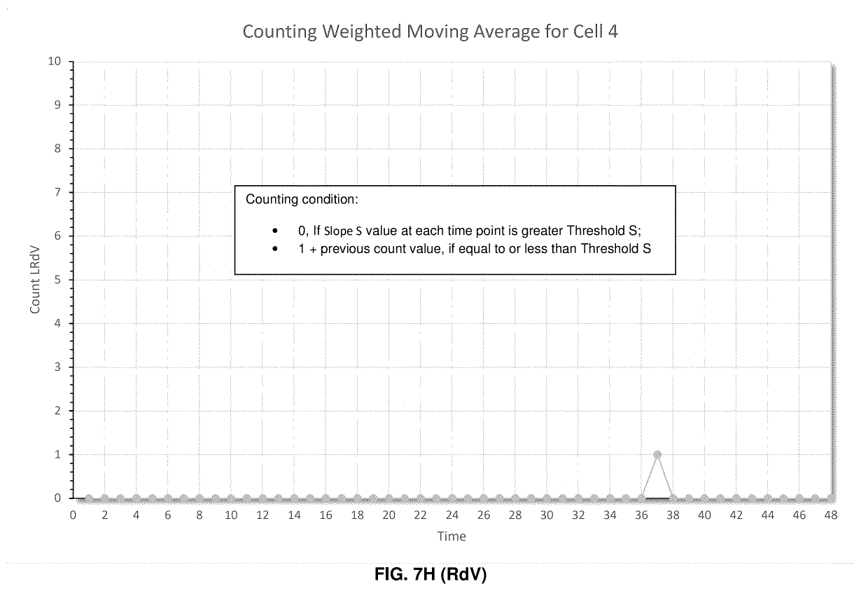

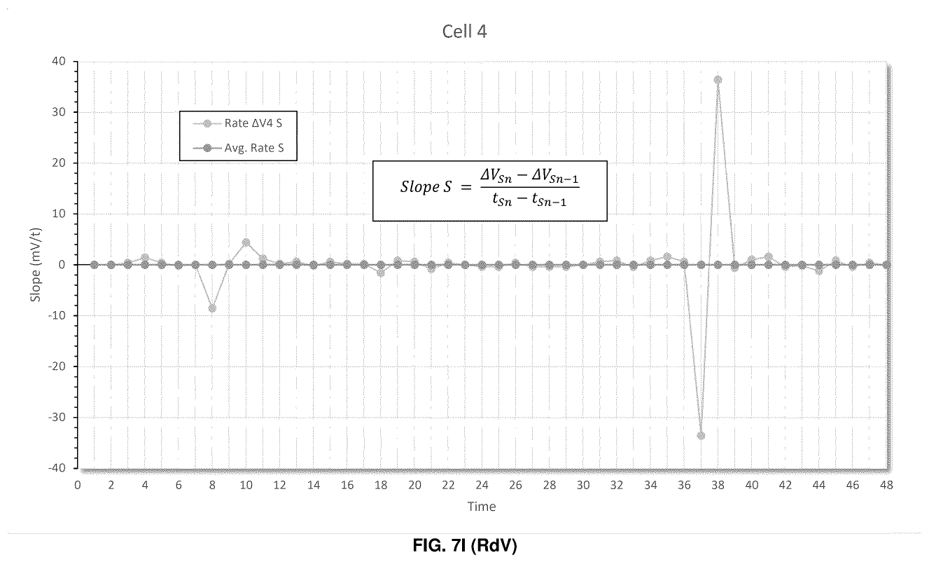

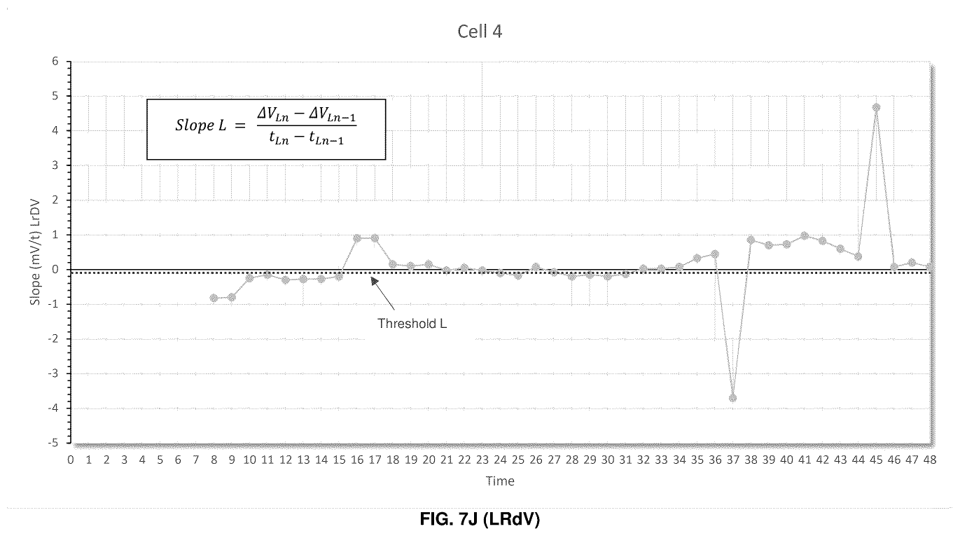

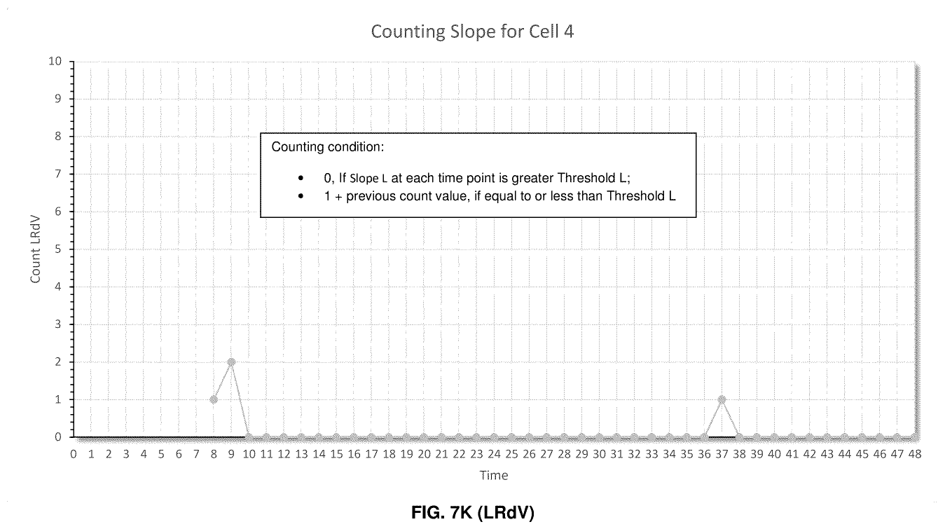

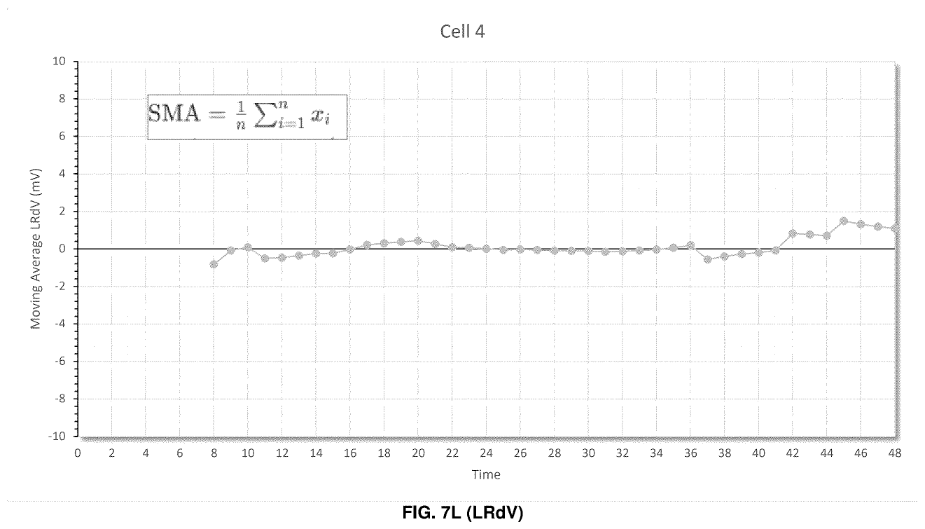

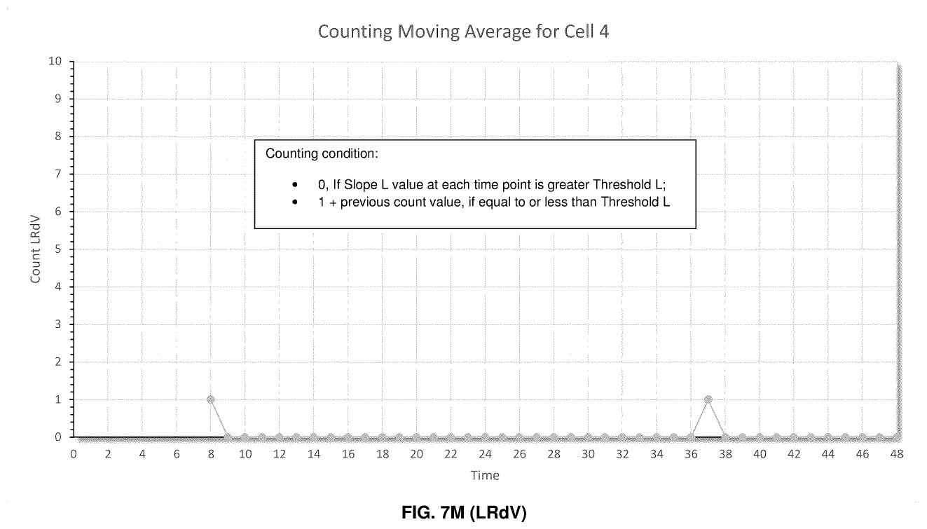

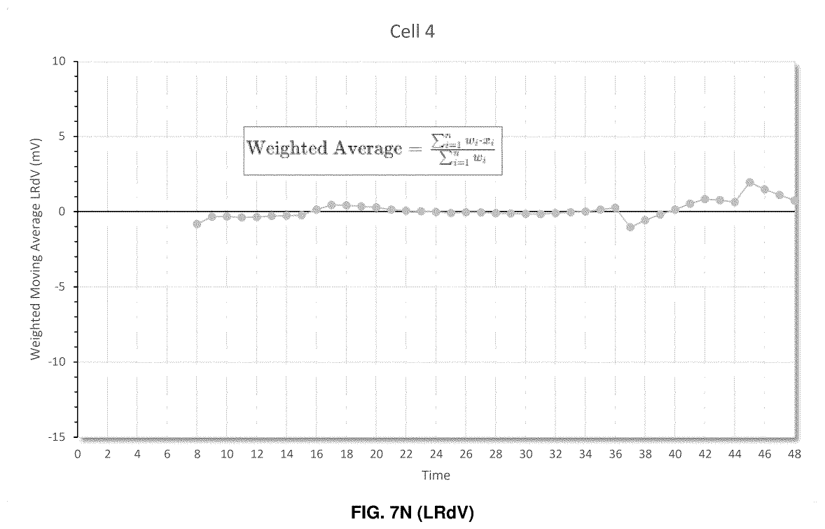

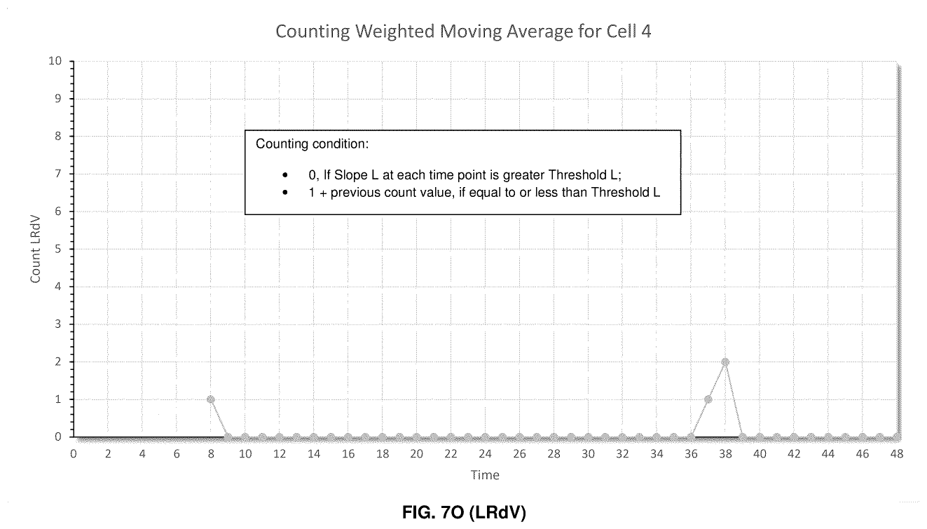

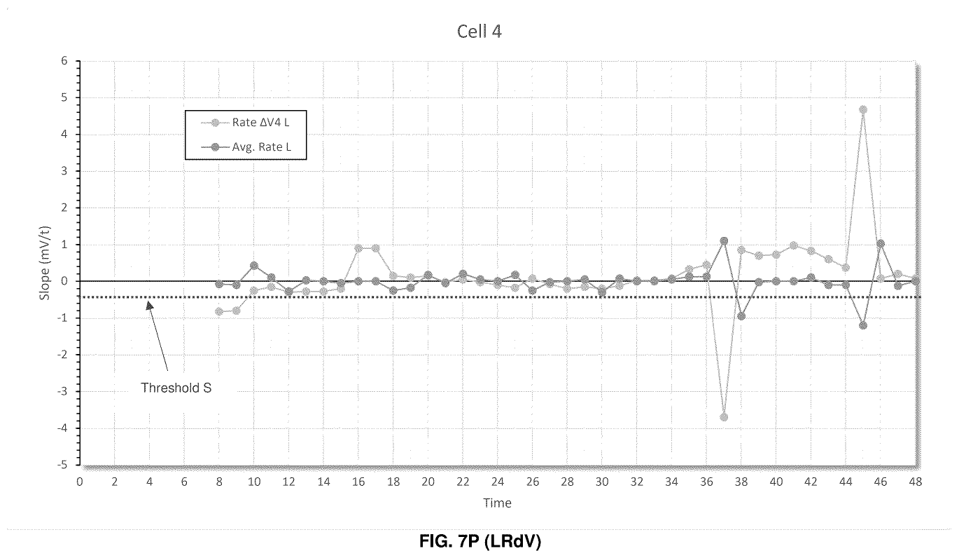

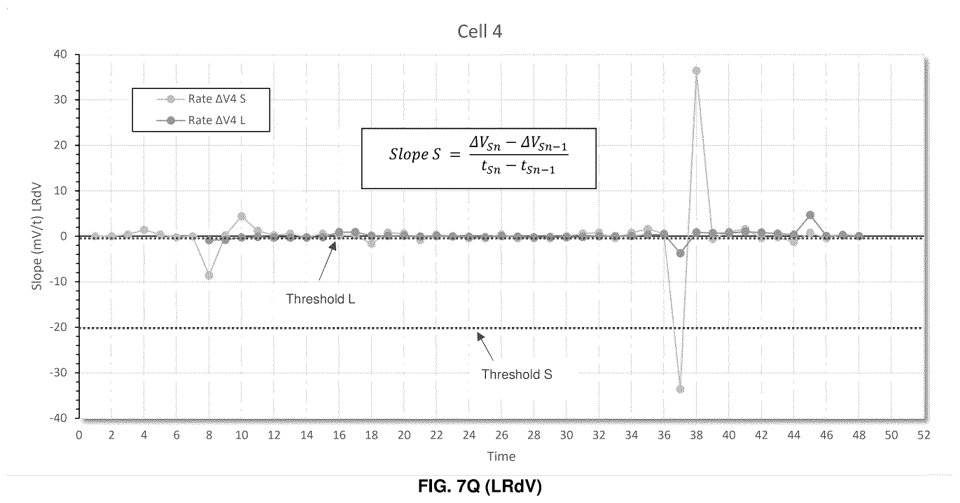

FIG. 7A illustrates the comparison between the OCV values of cell 4 and the average OCV values of the five cells, and FIG. 7B shows the differential values (ΔV=OCV for cell 4 −Avg. OCV) between the OCV measurements of cell 3 and the average OCV of the five cells at each measurement time point shown in FIG. 7A. These two graphs are similar to those in FIGS. 5A and 5B, but for cell 4, and the detailed description is omitted. Similarly, an example Slope L for cell 4 is determined by calculating the rate of change in ΔV between months 16 and 24 over an 8-month period, and an example Slope S is determined by calculating the rate of change in ΔV between months 37 and 38 over a 1-month period.

### Cell 1 Rate of Change of Differential Value (Slope S)

FIG. 5C illustrates the slope (e.g., Slope S), namely, the rate of change of the OCV difference values of cell 1 over a certain length of time, e.g., a 1-month duration of time shown in FIG. 5B. For instance, the slope of the OCV differential between time units t₂ and t₁ can be calculated by:

$$Slope ( {t}_{1} , {t}_{2} ) = \frac{OCV\_Differential ( {t}_{2} ) - OCV\_Differential ( {t}_{1} )}{{t}_{2} - {t}_{1}} .$$

This gives the rate of change of the OCV differential between two time units, and this is calculated for each cell and also for the overall OCV differential. In FIG. 5B, the vertical axis represents the slope, namely, the rate of change, while the horizontal axis represents time. A steep slope (indicating a large rate of change) could signify rapid degradation or abnormal behavior, such as an internal short circuit or excessive heat generation. The slope data is compared to a threshold, e.g., Threshold S, which is a predetermined value representing the maximum allowable voltage drop before fire occurs. If the slope exceeds this threshold, i.e., if cell 1's rate of voltage decrease over the certain duration of time is greater than this threshold, it may indicate that cell 1 is experiencing an abnormal condition that requires further investigation. The graph in FIG. 5C illustrates that there is no slope value, in absolute, greater than the absolute value of Threshold S (e.g., (−)20 mV/t) according to this example analysis. Alternatively, a rate of voltage (OCV) decrease and a rate of decrease of the composite (e.g., average) voltage for the multiple cells (e.g., 5 battery cells) can be compared to determined whether the rate of voltage (OCV) decrease is greater than the rate of decrease of the composite (e.g., average) voltage for the multiple cells by at least the predetermined threshold (e.g., Threshold S) over a predetermined length of time. This comparison approach can be represented by

$$\vert \frac{{OCV}_{i} ( {t}_{2} ) - {OCV}_{i} ( {t}_{1} )}{Δ t} - \frac{{OCV}_{avg} ( {t}_{2} ) - {OCV}_{avg} ( {t}_{1} )}{Δ t} \vert \geq {T}_{threshold} ,$$

where:
OCVᵢ(t): Open Circuit Voltage for the i-th cell at time t,
OCV_{avg}(t): Average Open Circuit Voltage of all cells at time t,
ΔOCVᵢ: Differential of OCV for the i-th cell calculated OCTᵢ(t₂)−OCVᵢ(t₁),
ΔOCV_{avg}: Differential of average OCV, calculated as OCV_{avg}(t₂)−OCV_{avg} (t₁),
Δt: Time interval between measurements,
T_{threshold}: Predetermined threshold value for rate of OCV decrease.
   These two comparison approaches would receive the same result because mathematically,

$$\frac{{OCV}_{i} ( {t}_{2} ) - {OCV}_{i} ( {t}_{1} )}{Δ t} - \frac{{OCV}_{avg} ( {t}_{2} ) - {OCV}_{avg} ( {t}_{1} )}{Δ t}$$

$$equals to$$

$$\frac{OCV\_Differential ( {t}_{2} ) - OCV\_Differential ( {t}_{1} )}{{t}_{2} - {t}_{1}} .$$

### Threshold S

Threshold S may be between 0 and about −40 mV/t or below about −40 mV/t, such as at or about −1, −2, −3, −4, −5, −6, −7, −8, −9, −10, −11, −12, −13, −14, −15, −16, −17, −18, −19, −20, −21,-22, −23, −24, −25, −26, −28, −29, −30, −31, −32, −33, −34, −35, −36, −37, −38, −39, −40, −41, −42, −43,-44, −45, −46, −47, −48, −49, or −50 mV/t etc. In embodiments, Threshold S may be within a range formed by any two numbers in the immediately preceding sentence, such as between 0 mV/t and about −20 mV/t, between about −20 mV/t and about −40 mV/t, between about −10 mV/t and about −30 mV/t, between about −12 mV/t and about −28 mV/t, between about −14 mV/t and about −26 mV/t, between about −16 mV/t and about −24 mV/t, between about −18 mV/t and about −22 mV/t, or between about −19 mV/t and about −21 mv/t, etc. In some embodiments, Threshold S may be between 0 and about −40 mV/t or greater than about 40 mV/t, such as at or about 1, 2, 3, 4, 5, 6, 7, 8, 9, 10, 11, 12, 13, 14, 15, 16, 17, 18, 19, 20, 21, 22, 23, 24, 25, −26, 28, 29, 30, 31, 32, 33, 34, 35, 36, 37, 38, 39, 40, 41, 42, 43, 44, 45, 46, 47, 48, 49, or 50 mV/t, etc. In embodiments, Threshold S may be within a range formed by any two numbers in the immediately preceding sentence, such as between 0 mV/t and about 20 mV/t, between about 20 mV/t and about 40 mV/t, between about 10 mV/t and about 30 mV/t, between about 12 mV/t and about 28 mV/t, between about 14 mV/t and about 26 mV/t, between about 16 mV/t and about 24 mV/t, between about 18 mV/t and about 22 mV/t, or between about 19 mV/t and about 21 mv/t, etc.

### Slope Threshold for Fire Risk

The threshold value(s) can be set using various combinations or criteria, such as the rate of change in OCV differential over a specified time window as described above or the cumulative OCV differential across multiple time intervals. For example, a threshold could be defined where an OCV differential slope exceeding −15 mV/t over a 10-minute length of time (or any length of time from 0 to 1 hour) may trigger an alert. As another example, a OCV differential slope exceeding −25 mV/t over a 5-minute length of time may trigger an alert. These two thresholds can also be used together. Different combinations of length of time and differential thresholds could be used depending on the battery chemistry, design, and application. This flexibility allows for tailored safety mechanisms, ensuring that the threshold is sensitive enough to detect dangerous conditions while accommodating a range of operational scenarios, making it a versatile approach for preventing battery-related fire risks.

### Cell 1 Count of Occurrences Below Threshold

The plot in FIG. 5C can be differently plotted to show how often the slope drops below the predetermined threshold, e.g., Threshold S, as illustrated in FIG. 5D. In this example, the vertical axis of FIG. 5D represents the count of occurrences, while the horizontal axis represents time or different measurement intervals. Every time the slope falls below the threshold, it signals that the battery is showing unusual behavior-specifically, that the rate of change in the OCV difference is faster than what is considered normal or acceptable. Keeping track of how often the slope falls below this threshold is an important tool for monitoring the battery's health. By counting these occurrences, it is possible to determine the likelihood of a problem, such as battery failure or potential fire risks. For example, if the count is one, it might simply be some minor issue, but if the count is more than two, it could indicate more serious concerns and the need for additional safety checks. Usually, the more the count is, the higher risk it indicates. In this specific example, since the slope has never dropped below the shorter-term threshold, i.e., the absolute value of the slope is never greater than the absolute value of the predetermined threshold, the count remains at zero, meaning the battery is operating normally and does not pose any immediate danger.

### Cell 2 Rate of Change of Differential Value (Slope S) and Count of Occurrences

FIG. 6C illustrates the slope (Slope S) of the OCV difference values over a 1-month period from FIG. 6B. FIG. 6D shows the count of occurrences where the slope, shown in FIG. 6C, falls below the short-term threshold (Threshold S). Similar to the example illustrated in FIGS. 5C and 5D, the OCV differential value for cell 2 does not drop faster than the threshold absolute values. This shows that the battery is operating within the expected range, with no significant issues detected.

### Cell 4 Rate of Change of Differential Value (Slope S) and Count of Occurrences

FIGS. 7C and 7D are presented in a similar way as previous figures. FIG. 7C shows the slope (Slope S) of the OCV difference values from FIG. 7B, while FIG. 7D illustrates the count of occurrences where the slope from FIG. 7C drops below the threshold (Threshold S). In contrast to cells 1 and 2, cell 4 has one instance where the OCV differential value drops faster than the threshold absolute value, specifically at the 37-time point mark. As a result, the count value in FIG. 7D is 1 at that time point. This count can be used to assess potential fire risk; for example, if there is at least one occurrence or more, it may signal a higher risk of fire, prompting further safety actions.

### Moving Average Analysis

The slope analysis mentioned earlier is just one example of how to predict potential risks in battery cells. In other cases, different data smoothing methods, such as Simple Moving Average (SMA) or Moving Average (MA), can be used with OCV data to detect unusual battery behaviors. These techniques help spot patterns like a slow decline or a sudden rise in the OCV, which could be signs of a fire risk. The MA method is a statistical approach that looks at time series data by smoothing out short-term changes, making it easier to see long-term trends. When applied to OCV data, the moving average calculates the average OCV over a specific time frame, helping identify any abnormal shifts in the battery's performance. For example, if the OCV of a battery cell increases or drops sharply beyond a certain limit, it could be a warning that the battery is failing or at risk of fire. The MA can be calculated over a fixed window, such as the average of the last 5, 10, or 15 measurements. As new OCV data is collected, the oldest value is dropped, creating a “moving” window that tracks changes over time. The SMA can be calculated by:

$$SMA = \frac{{A}_{1} + {A}_{2} + … + {A}_{n}}{n}$$

where:
Aₙ=the price of an asset at period n
n=the number of total periods
   For example, at each time unit t, the OCV of each of the 5 battery cells, e.g., C1, C2, C3, C4, C5, are measured, and the OCV of each cell at time t can be recorded as OCVc1(t), OCVc2(t), OCVc3 (t), OCVc4(t), OCVc5(t). The MA over a window of size n (length of time) can be used for this purpose. For C1 at time t within MA could be calculated as:

$${OCV}_{{C}_{i}}^{MA} ( t ) = \frac{{OCV}_{{C}_{i}} ( t - n + 1 ) + {OCV}_{{C}_{i}} ( t - n + 2 ) + … + {OCV}_{{C}_{i}} ( t )}{n}$$

### Cell 1 Moving Average Analysis

In FIG. 5E, the MA at 8 time units is a moving average of 4 short-term slope values. For example, slopes or rates of change in ΔV are 0.4 mV at 5 time units, −0.2 mV at 6 time units, 0 mV at 7 time units, and 3.4 mV at 8 time units. The average of these values for cell 1 (C1) in the timeframe spanning 4 time units is 0.9 mV, which is plotted in FIG. 5E (0.9 mV at 8 time units). The window of size n (length of time) can vary, e.g., 2, 3, 4, 5, 6, or the like, for each battery cell. Then, a similar analysis to the slope or rate of change can be applied to the MA data. That is, if the moving average of the slope data of a cell (e.g., cell 1) suddenly shifts past a pre-set threshold, it might suggest the battery is experiencing issues like overheating or component failure. Further, similar to how the rate of change occurrences were counted, the MA data is also compared with the threshold, and the number of occurrences it falls outside the threshold is counted, as shown in FIG. 5F.

### Pre-Set Threshold

The pre-set threshold may be between 0 and about −20 mV/t or below about −20 mV/t, such as at or about −1, −2, −3, −4, −5, −6, −7, −8, −9, −10, −11, −12, −13, −14, −15, −16, −17, −18, −19, −20, −21, −22, −23, −24, −25, −26, −28, −29, −30, −31, −32, −33, −34, −35, −36, −37, −38, −39, −40, −41, −42, −43, −44,-45, −46, −47, −48, −49, or −50 mV/t etc. In embodiments, the pre-set threshold may be within a range formed by any two numbers in the immediately preceding sentence, such as between 0 mV/t and about −20 mV/t, between about −20 mV/t and about −40 mV/t, between about −10 mV/t and about −30 mV/t, between about −12 mV/t and about −28 mV/t, between about −14 mV/t and about −26 mV/t, between about −16 mV/t and about −24 mV/t, between about −18 mV/t and about −22 mV/t, between about −19 mV/t and about −21 mv/t, between about −1 mV/t and about −5 mV/t, between about −5 mV/t and about −10 mV/t, between about −10 mV/t and about −15 mV/t, or between about −15 mV/t and about −20 mV/t, between about −4 mV/t and about −8 mV/t, or between about −5 mV/t and about −7 mv/t, etc. In some embodiments, the pre-set threshold may be between 0 and about 20 mV/t or greater than about 20 mV/t, such as at or about 1, 2, 3, 4, 5, 6, 7, 8, 9, 10, 11, 12, 13, 14, 15, 16, 17 18, 19, 20, 21, 22, 23, 24, 25, −26, 28, 29, 30, 31, 32, 33, 34, 35, 36, 37, 38, 39, 40, 41, 42, 43, 44, 45, 46, 47, 48, 49, or 50 mV/t, etc. In embodiments, Threshold S may be within a range formed by any two numbers in the immediately preceding sentence, such as between 0 mV/t and about 20 mV/t, between about 20 mV/t and about 40 mV/t, between about 10 mV/t and about 30 mV/t, between about 12 mV/t and about 28 mV/t, between about 14 mV/t and about 26 mV/t, between about 16 mV/t and about 24 mV/t, between about 18 mV/t and about 22 mV/t, or between about 19 mV/t and about 21 mv/t, between about 1 mV/t and about 5 mV/t, between about 5 mV/t and about 10 mV/t, between about 10 mV/t and about 15 mV/t, between about 15 mV/t and about 20 mV/t, between about 4 mV/t and about 8 mV/t, or between about 5 mV/t and about 7 mv/t, etc.

### Moving Average Analysis for Fire Risk Prediction

The moving average (MA) is used to smooth out transient fluctuations in OCV measurements, providing a more accurate and reliable indication of abnormal trends over time. This is particularly important for detecting potential fire risks, as it helps filter out short-term variations that may not be significant. To identify dangerous conditions, a pre-set threshold for the MA can be defined, such as a specific moving average slope, as previously described. An alert would be triggered if the rate of change in the OCV differential exceeds this threshold within a defined time window. The time window can be any length of time, such as instantly, 1 minute, 2 minutes, 5 minutes, 10 minutes, or 1 hour, etc. Additionally, the number of occurrences when the moving average exceeds the threshold can be monitored. If the absolute MA exceeds the threshold, for example, at least once, twice, three times, or more, an alert may be triggered. This dynamic and flexible approach enables continuous monitoring of the battery cells, providing a sensitive, adaptive mechanism to detect fire risk in real-time. By closely tracking the behavior of the OCV differential over time, potential fire risks can be detected promptly, thereby preventing hazardous conditions.

### Cell 2 and Cell 3 Moving Average Analysis

Moving average values are calculated and plotted for cell 2 and cell 4 comparison, as shown in FIGS. 6E and 7E, respectively. As seen, one moving average in cell 4 falls below the threshold, i.e., the absolute value thereof is greater than the absolute value of the threshold, which is consistent with the slope analysis results.

### Weighted Moving Average Analysis

The weighted moving average (WMA) is a more advanced form of the moving average where different weights are assigned to each data point within the time window. More recent data points may be given higher weights, reflecting their greater importance in predicting the battery's future behavior. This method is especially useful when the latest OCV values are considered more indicative of the battery's current state than older values. Similar to the MA, the WMA also calculates the average of OCV values within a specific cell over a specified period. The formular for WMA is:

$$WMA = \frac{{w}_{1} \cdot {x}_{1} + {w}_{2} \cdot {x}_{2} + … + {w}_{n} {x}_{n}}{{w}_{1} + {w}_{2} + … + {w}_{n}} ,$$

where x₁, x₂, . . . , xₙ are the data points (OCV values), and w₁, w₂, . . . , wₙ are the respective weights assigned to each point.
   If the most recent OCV values are disproportionately higher than previous values, it suggests that the specific battery cell may be behaving abnormally. By giving more weight to recent measurements, the WMA can help detect more immediate risks, such as a rapid OCV increase, which could indicate imminent failure.

### Cell 1, Cell 2, Cell 4 Weighted Moving Average Analysis

The WMA for each cell can be calculated as follows:

$$Weighted Moving {Average}_{i} ( t ) = {\sum }_{j = 0}^{n} {w}_{j} \cdot Differential {OCV}_{i} ( t - j )$$

### Where:

wⱼ are the weights applied to each differential OCV, with higher weights assigned to more recent data points.
n the number of previous time intervals considered in the moving average calculation.
   In FIGS. 5G, 5H, 6G, and 6H, the weighted average OCV data shows that, just like with the slope and simple moving average tests, everything is normal with battery cells 1 and 2 during the timeframe they are measured. For instance, the WMA value at 17 time units is −0.66 mV/t as the lowest value for cell 1 but above the threshold line, and WM value at 38 time units is −4.24 mV/t as the lowest value for cell 2 but above the threshold line. However, as shown in FIGS. 7G and 7H, cell 4 shows a possible sign of fire risk, consistent with the slope and simple moving average tests.

### Exponential Moving Average (EMA) for Rapid Detection

Another powerful way to analyze the OCV data is the Exponential Moving Average (EMA). This method is similar to a regular moving average but with a twist—it gives more weight to the most recent data points. This means that the EMA is very sensitive to recent changes, which makes it excellent at spotting sudden shifts in OCV. With this sensitivity, the EMA can quickly find any unusual behavior, which could help detect potential fire risks.

### Cumulative Sum (CUSUM) for Subtle Changes

Cumulative Sum (CUSUM), is good at detecting even the smallest changes over time. CUSUM works by tracking how much the data deviates from a set reference point. This helps catch subtle trends that may not be obvious at first. CUSUM is especially helpful for spotting gradual changes in OCV, which could signal problems that might not yet be severe.

### Machine Learning for Advanced Detection

For even more advanced detection, machine learning techniques can be used. These algorithms can study historical OCV data to learn how batteries normally behave. By doing this, they can identify when new data points fall outside of the expected patterns. This results in a highly advanced method for finding potential problems or fire risks in the battery apparatus.

### Combining Analysis Methods for Enhanced Safety

When combined, one or more methods like Moving Average (MA), Weighted Moving Average (WMA), Exponential Moving Average (EMA), Cumulative Sum (CUSUM), and machine learning-based anomaly detection can work alone or in combination in conjunction with the rate of change in OCV difference method to improve fire risk detection in battery systems. By continuously monitoring OCV values and applying these techniques, the system can detect potential hazards early. This early detection allows for quick action, helping to ensure safety in battery-powered systems.

### Exploring Other Data Analysis Methods

It is understood that these data analysis methods are merely for illustration and non-limiting. There are many other ways to analyze the OCV data. These different data analysis methods can be used to process any data in the method provided herein. In the non-limiting illustrative examples shown in the figures, these data analysis method (e.g., moving average) is used to process the slopes, i.e., the rates of change in the OCV differentials.

### Slope S of OCV Difference Alongside Average Slope

FIG. 5I compares the slope shown in FIG. 5C for battery cell 1 with the average slope for the five battery cells. This allows for a comparison between the behavior of one single cell and that of all the cells within the same system as whole, offering insights into whether the observed rate of change is normal or anomalous. The vertical axis represents the slope, and the horizontal axis represents time. A deviation from the average slope could indicate abnormal behavior specific to battery cell 1, which may be indicative of an increased fire risk.

### Combination of Data Analysis

The data analysis methods can be used alone or in combination. In some embodiments, one type of analysis may provide enough assessment to predict fire risk. In some embodiments, two types of data analysis can be used in combination or to supplement each other. In some other embodiments, three or more types of data analysis can be used to determine the fire risk, where all the conditions need to be satisfied.

### Long-Term Voltage Drop Analysis (Lrdv)

### Cell 1 Rate of Change of Differential Value (Slope L)

FIG. 5J depicts the slope (e.g. Slope L) of the OCV differential values (ΔV) shown in FIG. 5B over an 8-month period as an example predetermined length of time. The vertical axis represents the slope, while the horizontal axis represents time. This slope is compared to a predetermined threshold (Threshold L), which may be different from the threshold in FIG. 5C. For example, the Threshold S may be (−)20 mV/t, while the Threshold L may be about (−)0.5 mV/t or (−)0.5375 mV/t. These thresholds are not limited to those in the examples illustrated in the figures. If the slope surpasses the predetermined threshold, it could signal that the battery cell is undergoing an unusual condition warranting further examination. For instance, in this scenario, cell 1 encounters the anomaly at time point 45 units, e.g., months. Alternatively, a rate of voltage (OCV) decrease and a rate of decrease of the composite (e.g., average) voltage for the multiple cells (e.g., 5 battery cells) can be compared to determined whether the rate of voltage (OCV) decrease is greater than the rate of decrease of the composite (e.g., average) voltage for the multiple cells by at least the predetermined threshold (e.g., Threshold L) over a predetermined length of time. The mathematical calculations are the same as those in the above-described Short-Term voltage drop analysis.

### Threshold L

Threshold L may be between 0 to about −5 mV/t or below −5 mV/t, such as at or about −0.1, −0.15, −0.2, −0.25, −0.3, −0.35, −0.4, −0.45, −0.5, −0.55, −0.6, −0.65, −0.7, −0.75, −0.8, −0.85,-0.9, −0.95, −1, −1.5, −2, −2.5, −3, −3.5, −4, −4.5, −5, −5.5, −6, −6.5, −7, −7.5, −8, −8.5, −9, −9.5, or −10 mV/t, etc. In embodiments, Threshold L may be within a range formed by any two numbers in the immediately preceding sentence, such as between 0 mV/t and about −4 mV/t, between 0 mV/t and about −3 mV/t, between 0 mV/t and about −2 mV/t, between 0 mV/t and about −1 mV/t, between about −0.1 mV/t and about −0.8 mV/t, between about −0.2 mV/t and about −0.6 mV/t, between about −0.3 mV/t and about −0.55 mV/t, etc. In some embodiments, Threshold L may be between 0 to about 5 mV/t or greater than 5 mV/t, such as at or about 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.5, 2, 2.5, 3, 3.5, 4, 4.5, 5, 5.5, 6, 6.5, 7, 7.5, 8, 8.5, 9, 9.5, or 10 mV/t, etc. In embodiments, Threshold L may be within a range formed by any two numbers in the immediately preceding sentence, such as between 0 mV/t and about 4 mV/t, between 0 mV/t and about 3 mV/t, between 0 mV/t and about 2 mV/t, between 0 mV/t and about 1 mV/t, between about 0.1 mV/t and about 0.8 mV/t, between about 0.2 mV/t and about 0.6 mV/t, between about 0.3 mV/t and about 0.55 mV/t, etc.

Threshold L v. Threshold S

The threshold for the longer-term data analysis, i.e., Threshold L, may be substantially smaller than the threshold for the shorter-term data analysis, i.e., Threshold S. For instance, Threshold L may be at least, 50, 51, 52, 53, 54, 55, 56, 57, 58, 59, 60, 61, 62, 63, 74, 65, 66, 67, 68, 69, 70, 71, 72, 73, 74, 75, 76, 77, 78, 79, 80, 81, 82, 83, 85, 86, 87, 88, 89, 90, 91, 92, 93, 94, 95, 96, 97, 98, 99% smaller than Threshold S. It is understood that when comparing the thresholds, it is the absolute values of the thresholds that are being compared. For example, Threshold L may be−0.2 mV/t or 0.2 mV/t, and Threshold S may be −20 mV/t or 20 mV/t. In another example, Threshold L may be−0.5 mV/t or 0.5 mV/t, and Threshold S may be −10 mV/t or 10 mV/t. These examples are merely for illustrative purposes and are not limiting.

### Absolute Values Compared

When two data are compared in the methods provided herein, it is the absolute values of these two data that are compared. For example, although the values of the thresholds in the illustrations and examples provided herein are negative, when it is stated that a data exceeds a threshold, it means the absolute value of this data exceeds the absolute value of the threshold. Similarly, a data “falling below” a threshold also means the the absolute value of this data exceeds the absolute value of the threshold.

### Values of Thresholds

Although the voltage (e.g., OCV) of a battery may decline over time, the rate of voltage change, i.e., the slope, may fluctuate—it may increase or decrease and may be positive or negative over time (e.g., FIG. 5C). Although the values of the thresholds in the illustrations and examples provided in the figures are negative, it is understood that the thresholds can also be positive values. It is understood that whether the data involved in the methods provided herein are positive or negative values may depend on how the data are processed. For example, the absolute values and thus positive values of all data can be used.

### Cell 1 Count of Occurrences Below Threshold

FIG. 5K presents the count of occurrences where the slope shown in FIG. 5J falls below the threshold, i.e., the absolute value of the slope being greater than the absolute value of the threshold. The vertical axis shows the count, and the horizontal axis represents time or different measurement time points. The count of occurrences below the threshold indicates that the battery is exhibiting abnormal behavior. In this example, since no slope has passed the threshold, all the count values are 0.

### Cell 2 Slope of the OCV Difference and Count of Occurrence

FIG. 6J illustrates the slope (e.g., Slope L) of the OCV difference values shown in FIG. 6B over an 8-month period. In this illustration, the slope drops below the threshold (e.g., −0.5 mV/month) at the 40-unit (e.g., month) mark, indicating that the battery cell is at risk of fire. FIG. 6K shows the count of occurrences where the slope of battery cell 2 falls below the threshold as depicted in FIG. 6J. Since the slope starts dropping below the threshold at the 34-month mark, the count value starts at this mark. This count can be used to assess fire risk. For example, fire risk can be considered as soon as the slope meets the threshold, after a count of 2, or after a count of 3, etc. Through this, it can be seen that there is no fire risk in battery cell 1 (as shown in FIG. 5K), but there is a fire risk in battery cell 2 (as shown in FIG. 6K). Although the detailed description is omitted herein, cell 4 also has fire risk as shown in FIGS. 7J and 7K, which show that the slope falls below the threshold multiple times.

### Cell 1, 2, and 3 Moving Average and Weighted Moving Average Analysis

FIGS. 5L-5P for battery cell 1 show plots similar to FIGS. 5C-5I but focus on a longer duration of time using different data analysis methods, like moving average and weighted moving average. The same type of analysis is done for battery cell 2 in FIGS. 6L-6P and for battery cell 4 in FIGS. 6L-6P. The battery cells behave similarly in both short-term and long-term timeframes, showing some changes in the OCV drop. However, when looking at the data for a longer period, as shown in FIGS. 6J and 6K, with a smaller threshold for detection, more changes are spotted. For example, comparing the results from FIG. 6D (shorter timeframe analysis) to FIG. 6K (longer timeframe analysis), it becomes clear that a longer time of observation can detect fire risks that might be missed in the short-term analysis. This shows how important it is to use both short-term (steep voltage drop) and long-term (subtle voltage drop) analysis to properly monitor battery behavior and find potential problems

### Comparison of Steep and Gentle Slopes

FIGS. 5P, 6P, and 7P each show two different types of slopes side by side: one for the steep voltage drop and one for the subtle voltage drop. These comparisons help to understand how the same battery data can look different depending on the type of analysis used. The steep voltage drop slope analysis looks for big, sudden changes in the battery's OCV, while the subtle voltage drop slope analysis focuses on slower, smaller changes over time. Even though both analyses are looking at the same OCV data, the results can change depending on how the data is processed. For example, a rapid drop in OCV might be caught by the steep drop analysis, while a slower, smaller drop might only show up with the subtle drop analysis. This shows how both methods can find different types of battery behavior. Therefore, it is important to use both approaches together. By doing so, the chances of spotting potential problems, like a fire risk or other battery issues, are much higher, thus ensuring the battery apparatus' safety.

### Third Voltage Drop Analysis (FRDV)

### Daily Measured OCVs

FIGS. 8A-8J show data measured much more often than the data in FIGS. 3-7P. In FIGS. 3-7P, the OCV data was taken once a month for 48 time units, such as 48 months. But in this third voltage drop analysis, the measurements are taken daily for the five battery cells in one battery module. FIGS. 8A-8J are the “zoom in” figures on what was shown in FIGS. 3-5C, 5E, 5G, 5J, 5L, and 5N, respectively, for example, with daily measurements instead of monthly ones. By measuring the battery every day, it becomes easier to see small changes or “noise” that might not have been visible with just monthly measurements. These small changes could be important and might indicate something that would have been missed if the data was only collected less frequently, such as once a month. This closer, more frequent monitoring helps to detect details of how the battery is behaving day by day.

### Fire Risk Detection for Daily Measurements

The graphs with more frequent measurements show that sometimes the readings go way above both threshold lines, which could mean there is a high chance of fire risk. These graphs can catch risks that might have been missed otherwise. By measuring every day, it becomes easier to spot problems that might not have been noticed if the measurements were taken less frequently. This shows that more frequent measurements can help catch dangerous issues in time to fix them. However, some of these changes might just be random noise from the way the data is collected. Thus, using different ways to analyze the data can help make sure the fire risk is detected correctly.

### Battery Health Monitoring Process

### Method for Monitoring Battery Health and Detecting Risks

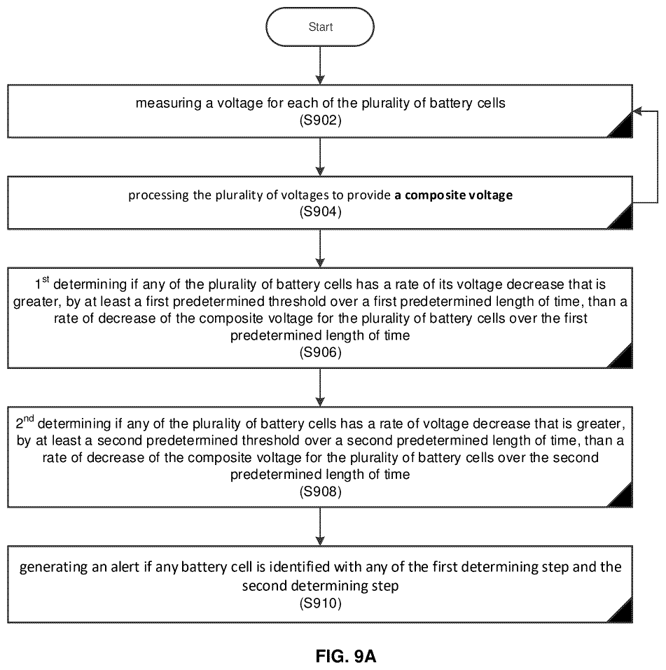

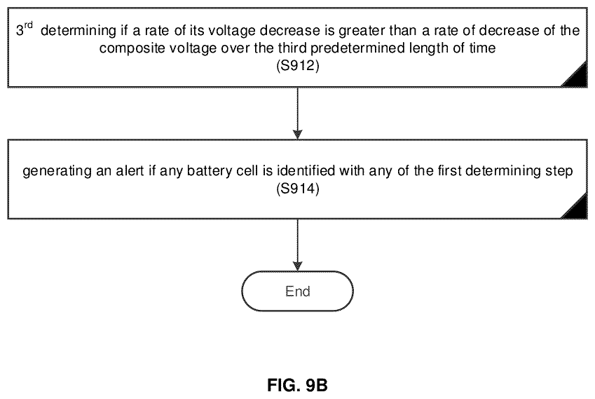

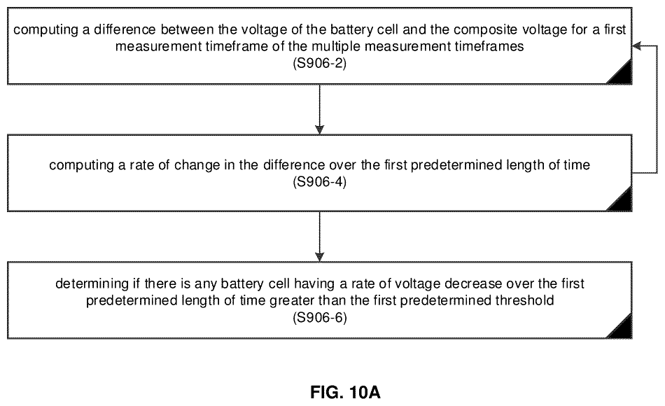

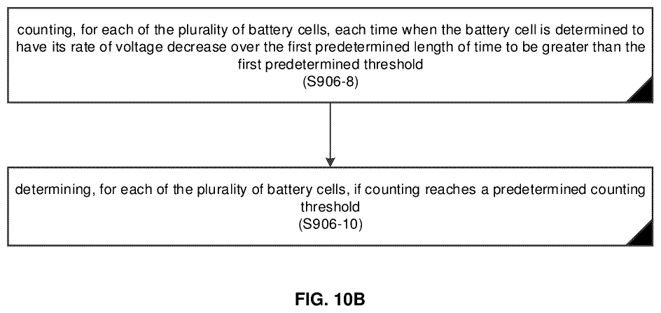

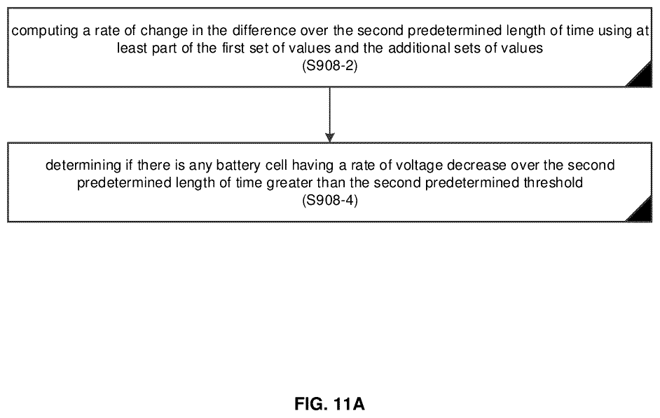

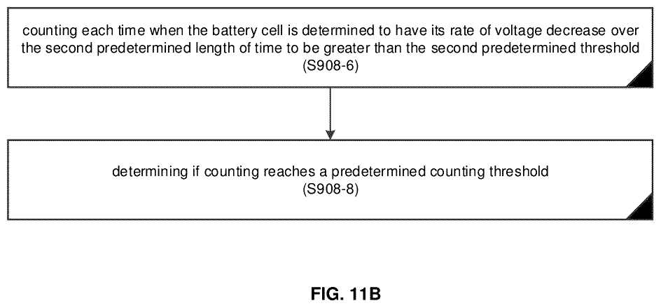

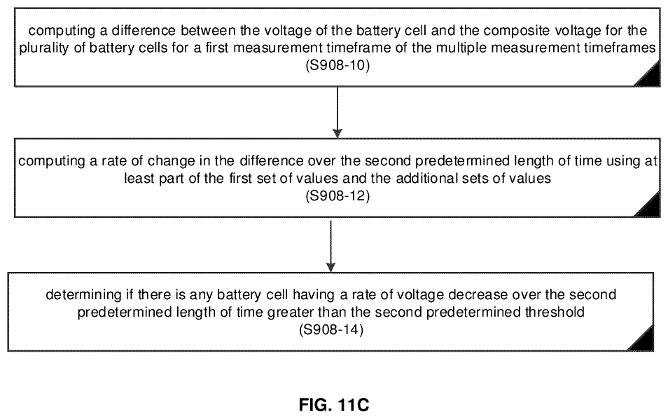

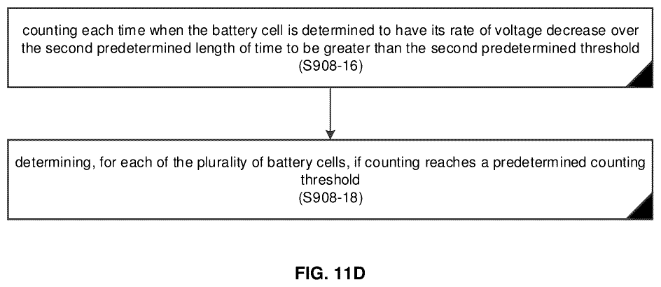

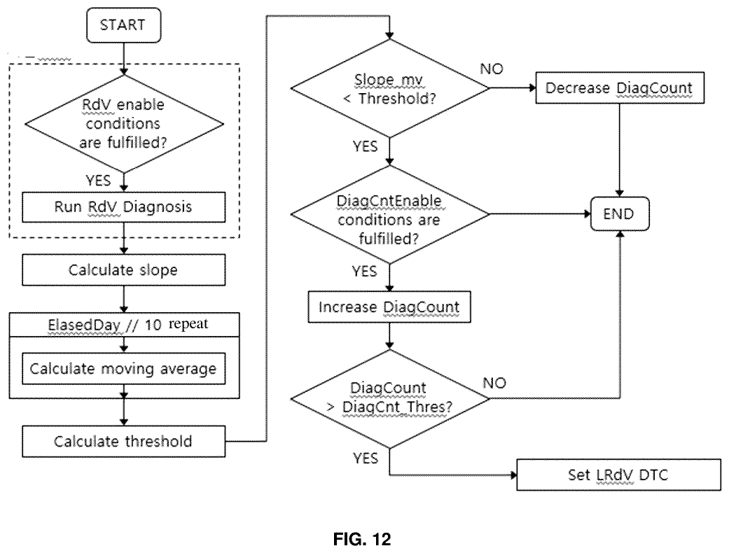

This section reiterates the method of monitoring a battery's health as provided in this disclosure, as illustrated in the flowcharts of FIGS. 9A-12, which are provided alongside the previously described exemplary graphs. FIG. 9 shows process 900, which outlines a method for diagnosing the health of a battery, according to one embodiment of the present disclosure. The method ensures that batteries remain safe and in good condition. Batteries are used in many devices, including phones, laptops, and electric cars. Occasionally, a battery may start to experience issues, such as losing power too quickly, which could become dangerous. This method helps monitor the battery's health by tracking its voltage over time. Voltage represents the energy level of the battery. If the battery shows signs of problems, such as rapid power loss, an alert may be generated to notify users. This allows for detection of issues before they become more serious.

### Measuring and Processing Battery Cell Voltage

Process 900 begins by measuring the voltage of each battery cell at a specific moment in time in step S902. The voltage may be measured at the single measurement timeframe simultaneously or consecutively for the plurality of battery cells, such that measurements for the plurality of battery cells are completed within a generally same timeframe. The voltages of the battery cells can be measured at the same time, either in perfect synchronization or within overlapping timeframes. The voltages of the battery cells can also be measured one after another in a sequential order, without interruption or overlap. Either way, all the voltage measurements for the plurality of battery cells are completed within a similar period, though not necessarily at the exact same moment; and all the measurements are taken close enough in time to be considered part of the same timeframe, even if there are slight overlaps or short gaps between them. Each battery cell can be thought of as a small battery within the larger battery. The voltage of each cell is checked to determine how much power it holds. These voltages are then recorded, creating a list of numbers that represent the power level of each individual cell at that moment. After the voltage of each battery cell is measured, the next step is to combine these voltages to calculate a composite voltage in step S904. The composite voltage can be an average voltage of multiple or all the battery cells. This provides an overall understanding of the battery apparatus' condition. To gain a more accurate understanding of how the battery is performing, the voltage of each cell is measured multiple times over a duration of time, such as a period of days or weeks. Each voltage reading is recorded, contributing to a clearer picture of the battery's health. With repeated measurements, a more reliable assessment of the battery's behavior is formed.

### Repeating Composite Voltage

After each set of voltage measurements is taken, the composite (e.g., average) voltage is calculated again. This helps to see if the battery's performance is changing over time. The process can be repeated multiple times to ensure the battery is regularly checked.

### Finding Any Major Voltage Drops (First Check)

Now, the method checks if any battery cells have a big drop in voltage in step S906. If one of the little batteries drops its power faster than a certain limit (e.g., a shorter-term threshold), this could be a sign that something is wrong. The shorter-term threshold is like a warning light that goes off when a problem starts. This step checks whether the battery cells are losing power too quickly, which could be a sign of trouble.

### Looking for Even Bigger Voltage Drops (Second Check)

In step S908, the method looks for even bigger drops in power, using a bigger limit (e.g., a longer-term threshold). This second check looks for more serious problems. If a battery cell loses power too fast, it could mean the battery is about to fail, so it needs to be fixed or replaced soon. The longer-term threshold is set substantially smaller than the shorter-term threshold to catch the more serious problems.

Sending Alert for First and/or Second Check

If any battery cells are found to be losing power too quickly, an alert is triggered in step S910. The alert serves as a warning This alert notifies users that the battery should be inspected, replaced, and/or repaired to prevent further issues. The alert can take various forms, including visual cues, sounds, vibrations, or other sensory signals. A non-limiting illustrative example of an alert can be a message saying, “Attention: A problem has been detected with this battery! It may pose a safety risk!”

### Looking Even Closer at Smaller Problems (Third Check)

To be even more careful, the method may further look at smaller problems that might not seem as bad at first but could get worse in step S912. This is the third check, where it looks at even smaller drops in power over a short amount of time. If the drop in power is big enough, it can still be a warning sign of a future problem. This step helps catch even the small signs of trouble. Sometimes, small drops in power happen naturally, and they don't mean there's a problem with the battery. Therefore, the method checks to make sure that small changes in power are not mistaken for big problems. This step makes sure that only real issues are flagged.

### Sending Alert for Third Check

The individual cell measurements are compared to the module's average OCV. If any abnormal differences are detected, the system evaluates the data against predetermined thresholds to assess the severity of the anomaly. If the differences exceed the thresholds, an alert is generated in step S914, indicating the potential for a failure or fire risk. The system can also provide a detailed analysis of the OCV trends, allowing for the identification of both short-term and long-term degradation patterns.

### Calculating the Rate of Change in Voltage Differences

First and second checking steps S906 and S908 each may include sub-steps (e.g., S906-2 through S906-10 and S908-2 through S908-18). These sub-steps make sure that the method checks all the battery cells at the same time, or as close to the same time as possible. By measuring all the cells together, it makes sure the results are accurate and fair. In addition, as time passes, the method also looks at how fast the battery's voltage is changing. For instance, the method checks the difference in voltage between each cell and the average voltage to see if the change is happening too quickly. This helps find any battery cells that are acting strangely. If a battery cell keeps having problems over time, it gets counted. The method keeps track of how many times a problem happens and when it happens. If a battery cell has too many problems, it gets flagged, and an alert is generated. This helps to make sure the issue does not go unnoticed.

### Example of Voltage Change Calculation

For every timeframe, the difference between the voltage of each individual cell and the composite voltage is computed. For example, if the voltage of a specific cell drops from 3.8V to 3.6V in a given timeframe, the difference would be 0.2V. This calculation is performed for each cell at each measurement timeframe. After gathering the differences for all cells over multiple timeframes, the rate at which each cell's voltage changes (decreases) over time is calculated. This rate is computed over the first, second, or third predetermined time intervals. If a cell's voltage decrease exceeds the predefined threshold during any timeframe, the system considers this a potential problem and generates an alert.

### Counting Occurrences of Significant Voltage Decreases

If a specific cell consistently shows significant voltage drops over multiple timeframes, the system keeps track of how often this happens. Each time the cell's data exceeds the threshold, a counter is incremented. Once the counter reaches a specific, predetermined threshold (for example, if a cell's voltage drop exceeds the threshold three times in a row), the system may automatically generate an alert. This alert notifies the user that a specific cell is experiencing issues and requires attention.

### Generating Alerts

After all the steps have been completed, if any battery cell is found to be having problems, an alert may be generated. This alert tells the user that something is wrong with the battery, and it may need to be fixed or replaced. By doing all these checks, the method provided herein keeps the battery safe and ensures its proper performance. This way, problems can be detected before they become big, dangerous issues. This method makes it easy to know when a battery is healthy and when it needs attention making sure the battery stays safe and works properly for a long time. The alert generated can include several types of information, such as, battery health alert for suggesting the battery may need maintenance or replacement, service suggestion for recommending that the battery system be checked for potential faults, and replacement suggestion for, if a cell is consistently underperforming, it may need to be replaced, etc.

### Computing System

### General Architecture

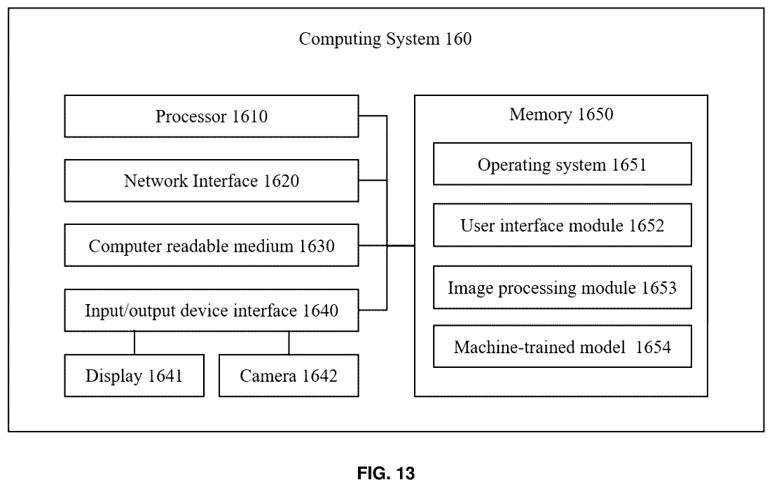

FIG. 13 depicts an example architecture of a computing system 160 that can be used to perform one or more of the techniques described herein and/or illustrated in other drawings. The general architecture of the computing system 160 may include an arrangement of computer hardware and software modules that may be used to implement one or more aspects of the present disclosure. The computing system 160 may include many more (or fewer) elements than those shown in FIG. 13. It is not necessary that all of these elements be shown in order to provide an enabling disclosure.

### Hardware

As illustrated, the computing system 160 includes a processor 1610, a network interface 1620, a computer readable medium 1630, and an input/output device interface 1640, all of which may communicate with one another by way of a communication bus. The network interface 1620 may provide connectivity to one or more networks or computing systems. The processor 1610 may also communicate with memory 1650 and further provide output information for one or more output devices, such as a display (e.g., display 1641), speaker, etc., via the input/output device interface 1640. The input/output device interface 1640 may also accept input from one or more input devices, such as a camera 1642 (e.g., 3D depth camera), a keyboard, a mouse, a digital pen, a microphone, a touch screen, a gesture recognition system, a voice recognition system, an accelerometer, a gyroscope, a thermometer, an optical temperature measurement system, a sonar, a LIDAR device, a laser device, etc.

### Software—Computer Program Instructions

The memory 1650 may store computer program instructions (grouped as modules in some implementations) that the processor 1610 executes in order to implement one or more aspects of the present disclosure. The memory 1650 may include RAM, ROM, and/or other persistent, auxiliary, or non-transitory computer-readable media. The memory 1650 may store an operating system 1651 that provides computer program instructions for use by the processor 1610 in the general administration and operation of the computing system 160. The memory 1650 may further include computer program instructions and other information for implementing one or more aspects of the present disclosure. In one implementation, for example, the memory 1650 includes a user interface module 1652 that generates user interfaces (and/or instructions therefor) for display, for example, via a browser or application installed on the computing system 160. In addition to and/or in combination with the user interface module 1652, the memory 1650 may include an image processing module 1653, a machine-trained model 1654 that may be executed by the processor 1610. The operations and algorithms of the modules are described in greater detail above with reference to other drawings.

### Multiple Components

Although a single processor, a single network interface, a single computer readable medium, a singer input/output device interface, a single memory, a single camera, and a single display are illustrated in the example of FIG. 13, in other implementations, the computing system 160 can have a multiple of one or more of these components (e.g., two or more processors and/or two or more memories).

### Other Considerations

Logical blocks, modules or units described in connection with implementations disclosed herein can be implemented or performed by a computing device having at least one processor, at least one memory and at least one communication interface. The elements of a method, process, or algorithm described in connection with implementations disclosed herein can be embodied directly in hardware, in a software module executed by at least one processor, or in a combination of the two. Computer-executable instructions for implementing a method, process, or algorithm described in connection with implementations disclosed herein can be stored in a non-transitory computer readable storage medium.

### Other Considerations

Although the implementations of the inventions have been disclosed in the context of certain implementations and examples, it will be understood by those skilled in the art that the present disclosures extend beyond the specifically disclosed implementations to other alternative implementations and/or uses of the inventions and obvious modifications and equivalents thereof. In addition, while a number of variations of the inventions have been shown and described in detail, other modifications, which are within the scope of the inventions, will be readily apparent to those of skill in the art based upon this disclosure. It is also contemplated that various combinations or sub-combinations of the specific features and aspects of the implementations may be made and still fall within one or more of the inventions. Accordingly, it should be understood that various features and aspects of the disclosed implementations can be combined with or substituted for one another in order to form varying modes of the disclosed inventions. Thus, it is intended that the scope of the present disclosures herein disclosed should not be limited by the particular disclosed implementations described above, and that various changes in form and details may be made without departing from the spirit and scope of the present disclosure as set forth in the following claims.

What is claimed is:

1. A method concerning on a battery's health, the method comprising:
providing a battery apparatus comprising a plurality of battery cells;
measuring a voltage for each of the plurality of battery cells at a single measurement timeframe, which provides a plurality of voltages of the plurality of battery cells measured at the single measurement timeframe;
processing the plurality of voltages for the plurality of battery cells measured at the single measurement timeframe to provide a composite voltage for the plurality of battery cells for the single measurement timeframe;
repeating the step of measuring a voltage multiple times to provide multiple voltages for each battery cell measured at multiple measurement timeframes, which provides multiple sets of voltages for the plurality of battery cells such that each set of voltages represents voltages for the plurality of battery cells measured at one of the multiple measurement timeframes;
repeating the step of processing each set of voltages to provide multiple composite voltages for the plurality of battery cells such that each of the multiple composite voltages represents a composite voltage for the plurality of battery cells at one of the multiple measurement timeframes;
first determining if any of the plurality of battery cells has a rate of its voltage decrease that is greater, by at least a first predetermined threshold over a first predetermined length of time, than a rate of decrease of the composite voltage for the plurality of battery cells over the first predetermined length of time;
second determining if any of the plurality of battery cells has a rate of voltage decrease that is greater, by at least a second predetermined threshold over a second predetermined length of time, than a rate of decrease of the composite voltage for the plurality of battery cells over the second predetermined length of time; and
generating an alert if any battery cell is identified with any of the first determining step and the second determining step,
wherein the first predetermined threshold is substantially smaller than the second predetermined threshold while the first predetermined length of time is longer than the second predetermined length of time such that the first determining step is to identify any battery cell that has its voltage decreasing substantially slower than any battery cell that would be identified with the second determining step and therefore would not be identified with the second determining step.

2. The method of claim 1, wherein the voltage measured is an open circuit voltage (OCV), wherein the composite voltage is an average voltage.

3. The method of claim 1, wherein no alert is generated even if any of the plurality of battery cells has a rate of voltage decrease being greater, by at least the first predetermined threshold over a third predetermined length of time, than a rate of decrease of the composite voltage for the plurality of battery cells over the third predetermined length of time when the third predetermined length of time shorter than the second predetermined length of time and further when the rate of voltage decrease for any of the plurality of battery cells is within an acceptable range of fluctuation of the rate of voltage decrease for individual cells over the third predetermined length of time.

4. The method of claim 3, wherein the third predetermined length of time is within a range formed with two ones selected from the group consisting of 1 hour, 2 hours, 3 hours, 4 hours, 5 hours, 6 hours, 7 hours, 8 hours, 10 hours, 11 hours, 12 hours, 13 hours, 14 hours, 15 hours, 16 hours, 17 hours, 18 hours, 19 hours, 20 hours, 21 hours, 22 hours, 23 hours, 1 day, 2 days, 3 days, 4 days, 5 days, 6 days, 7 days, 8 days, 9 days, and 10 days.

5. The method of claim 3, wherein the acceptable range of fluctuation is within a range formed with two ones selected from the group consisting of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50 mV/t.

6. The method of claim 1, wherein the alert comprises information suggesting a consultation about the battery's health, suggesting a service with regard to the battery apparatus, and/or replacing at least part of the battery apparatus.

7. The method of claim 1, further comprising:
third determining if any of the plurality of battery cells has a rate of its voltage decrease that is greater, by a third predetermined threshold over a third predetermined length of time, than a rate of decrease of the composite voltage for the plurality of battery cells over the third predetermined length of time; and
generating an alert if any battery cell is identified with any of the first determining step, the second determining step, and the third determining step,
wherein the second predetermined threshold is substantially smaller than the third predetermined threshold while the third predetermined length of time is shorter than the second predetermined length of time.

8. The method of claim 7, wherein no alert is generated even if any of the plurality of battery cells has a rate of voltage decrease being greater, by at least the first predetermined threshold over the third predetermined length of time, than the rate of decrease of the composite voltage for the plurality of battery cells over the third predetermined length of time when the rate of voltage decrease for any of the plurality of battery cells is within an acceptable range of fluctuation of the rate of voltage decrease for individual cells over the third predetermined length of time.

9. The method of claim 1, wherein measuring the voltage for each of the plurality of battery cells at the single measurement timeframe occurs simultaneously or consecutively such that measurements for the plurality of battery cells are completed within a generally same timeframe.

10. The method of claim 1, wherein the step of first determining comprises:
for each of the plurality of battery cells, computing a difference between the voltage of the battery cell and the composite voltage for the plurality of battery cells for a first measurement timeframe of the multiple measurement timeframes, which provides a first set of values for the difference for the plurality of battery cells for the first measurement timeframe such that the first set of values comprises a value for the difference for each of the plurality of cells for the first measurement timeframe;
repeating the step of computing a difference for additional measurement timeframes of the multiple timeframes, which provides additional sets of values for the difference for the plurality of battery cells for the additional measurement timeframes such that each set of values comprises a value for the difference for each of the plurality of cells for one measurement timeframe of the additional measurement timeframes;
for each of the plurality of battery cells, computing a rate of change in the difference over the first predetermined length of time using at least part of the first set of values and the additional sets of values; and
determining if there is any battery cell having a rate of voltage decrease over the first predetermined length of time greater than the first predetermined threshold using the computed rate of change for each of the plurality of battery cells.

11. The method of claim 10, wherein the step of computing a rate of change in the difference over the first predetermined length of time computes the rate of change in the difference for the first predetermined length of time beginning at the first measurement timeframe,
wherein the step of first determining further comprises:
for each of the plurality of battery cells, repeating the step of computing a rate of change in the difference over the first predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes; and
using at least part of the rates of change in the difference as computed for each of the plurality of battery cells to determine if there is any battery cell having a rate of voltage decrease over the first predetermined length of time greater than the first predetermined threshold for the first predetermined length of time beginning at one or more of the additional measurement timeframes.

12. The method of claim 11, wherein, when at least one of the plurality of battery cell is determined to have its rate of voltage decrease greater than the first predetermined threshold over the first predetermined length of time beginning any of the measurement timeframes, the battery cell is identified, which causes generating the alert.

13. The method of claim 11, wherein the step of first determining further comprises:
counting, for each of the plurality of battery cells, each time when the battery cell is determined to have its rate of voltage decrease over the first predetermined length of time to be greater than the first predetermined threshold; and
determining, for each of the plurality of battery cells, if counting reaches a predetermined counting threshold.

14. The method of claim 13, wherein, when counting for one of the plurality of battery cell reaches the predetermined counting threshold, the battery cell is identified, which causes generating the alert.

15. The method of claim 10 wherein the step of second determining comprises:
for each of the plurality of battery cells, computing a rate of change in the difference over the second predetermined length of time using at least part of the first set of values and the additional sets of values; and
determining if there is any battery cell having a rate of voltage decrease over the second predetermined length of time greater than the second predetermined threshold using the computed rate of change for each of the plurality of battery cells.

16. The method of claim 15, wherein the step of computing a rate of change in the difference over the second predetermined length of time computes the rate of change in the difference for the second predetermined length of time beginning at the first measurement timeframe or another measurement timeframe,
wherein the step of second determining further comprises:
for each of the plurality of battery cells, repeating the step of computing a rate of change in the difference over the second predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes; and
using at least part of the rates of change in the difference as computed for each of the plurality of battery cells to determine if there is any battery cell having a rate of voltage decrease over the second predetermined length of time greater than the second predetermined threshold for the second predetermined length of time beginning at one or more of the additional measurement timeframes.

17. The method of claim 16, wherein, when at least one of the plurality of battery cell is determined to have its rate of voltage decrease greater than the second predetermined threshold over the second predetermined length of time beginning any of the measurement timeframes, the battery cell is identified, which causes generating the alert.

18. The method of claim 16, wherein the step of second determining further comprises:
counting, for each of the plurality of battery cells, each time when the battery cell is determined to have its rate of voltage decrease over the second predetermined length of time to be greater than the second predetermined threshold; and
determining, for each of the plurality of battery cells, if counting reaches a predetermined counting threshold.

19. The method of claim 17, wherein, when counting for one of the plurality of battery cell reaches the predetermined counting threshold, the battery cell is identified, which causes generating the alert.

20. The method of claim 1, wherein the step of second determining comprises:
for each of the plurality of battery cells, computing a difference between the voltage of the battery cell and the composite voltage for the plurality of battery cells for a first measurement timeframe of the multiple measurement timeframes, which provides a first set of values for the difference for the plurality of battery cells for the first measurement timeframe such that the first set of values comprises a value for the difference for each of the plurality of cells for the first measurement timeframe;
repeating the step of computing a difference for additional measurement timeframes of the multiple timeframes, which provides additional sets of values for the difference for the plurality of battery cells for the additional measurement timeframes such that each set of values comprises a value for the difference for each of the plurality of cells for one measurement timeframe of the additional measurement timeframes;
for each of the plurality of battery cells, computing a rate of change in the difference over the second predetermined length of time using at least part of the first set of values and the additional sets of values; and
determining if there is any battery cell having a rate of voltage decrease over the second predetermined length of time greater than the second predetermined threshold using the computed rate of change for each of the plurality of battery cells.

21. The method of claim 20, wherein the step of computing a rate of change in the difference over the second predetermined length of time computes the rate of change in the difference for the second predetermined length of time beginning at the first measurement timeframe or another measurement timeframe,
wherein the step of second determining further comprises:
for each of the plurality of battery cells, repeating the step of computing a rate of change in the difference over the second predetermined length of time beginning at one or more of the additional measurement timeframes, which provides rates of change in the difference for each of the plurality of battery cells such that each of the rates of change in the difference for each of the plurality of battery cells represents the rate of change for the battery cell for one of the one or more of the additional measurement timeframes; and
using at least part of the rates of change in the difference as computed for each of the plurality of battery cells to determine if there is any battery cell having a rate of voltage decrease over the second predetermined length of time greater than the second predetermined threshold for the second predetermined length of time beginning at one or more of the additional measurement timeframes.

22. The method of claim 21, wherein, when at least one of the plurality of battery cell is determined to have its rate of voltage decrease greater than the second predetermined threshold over the second predetermined length of time beginning any of the measurement timeframes, the battery cell is identified, which causes generating the alert.

23. The method of claim 22, wherein the step of second determining further comprises:
counting, for each of the plurality of battery cells, each time when the battery cell is determined to have its rate of voltage decrease over the second predetermined length of time to be greater than the second predetermined threshold; and
determining, for each of the plurality of battery cells, if counting reaches a predetermined counting threshold.

24. The method of claim 23, wherein, when counting for one of the plurality of battery cell reaches the predetermined counting threshold, the battery cell is identified, which causes generating the alert.

25. A non-transitory computer readable medium storing instructions that, when executed, performs the method of claim 1.
